(19) United States
(12) Patent Application Publication
(10) Pub. No.: US 2025/0228136 A1
(43) Pub. Date: Jul. 10, 2025

(54) VARIABLE RESISTANCE MEMORY DEVICE

(71) Applicant: Samsung Electronics Co., Ltd., Suwon-si (KR)

(72) Inventors: Wonhyeok Heo, Suwon-si (KR); Youngkeol Kim, Suwon-si (KR); Hyunchul Shin, Suwon-si (KR); Junghoon Bak, Suwon-si (KR)

(21) Appl. No.: 18/978,020

(22) Filed: Dec. 12, 2024

(30) Foreign Application Priority Data
Jan. 4, 2024 (KR) 10-2024-0001669

(51) Int. Cl. H10N 50/10; G11C 11/16; H10B 61/00; H10N 50/85

(52) U.S. Cl. CPC H10N 50/10; G11C 11/1673; G11C 11/1675; H10B 61/22; H10N 50/85

(57) ABSTRACT

A variable resistance memory device includes a substrate including a first region and a second region, a plurality of memory cells disposed in the first region and each memory cell of the plurality spaced apart from each other, a buried layer pattern buried adjacent memory cells of the between the plurality of memory cells in the first region, the buried layer pattern including a first buried layer pattern filling a lower portion of each of the plurality of memory cells, and a second buried layer pattern filling an upper portion of each of the plurality of memory cells on the first buried layer pattern, and the first buried pattern layer including a first material and the second buried layer pattern including a second material different from the first material, and an interlayer insulating layer pattern disposed in the second region and including the first material.

### CROSS-REFERENCE TO RELATED APPLICATION

This application is based on and claims priority under 35 U.S.C. § 119 to Korean Patent Application No. 10-2024-0001669, filed on Jan. 4, 2024, in the Korean Intellectual Property Office, the disclosure of which is incorporated by reference herein in its entirety.

### BACKGROUND

The inventive concept relates to a variable resistance memory device, and more particularly, to a variable resistance memory device with improved reliability.

Memory devices used in semiconductor products need increased operating speeds and increased integration. Variable resistance memory devices have been proposed to satisfy such requirements. Variable resistance memory devices may use current transfer characteristics of a variable resistance layer according to an applied voltage. A representative example of variable resistance memory devices may be magnetoresistive random-access memory (MRAM).

### SUMMARY

The inventive concept provides a variable resistance memory device having improved reliability.

According to an aspect of the inventive concept, there is provided a variable resistance memory device including a substrate including a first region and a second region, a plurality of memory cells disposed in the first region and each memory cell of the plurality spaced apart from each other, a buried layer pattern buried between adjacent memory cells of the plurality of memory cells in the first region, the buried layer pattern including a first buried layer pattern filling a lower portion of each of the plurality of memory cells, and a second buried layer pattern filling an upper portion of each of the plurality of memory cells on the first buried layer pattern, and the first buried pattern layer including a first material and the second buried layer pattern including a second material different from the first material, and an interlayer insulating layer pattern disposed in the second region and including the first material.

According to another aspect of the inventive concept, there is provided a variable resistance memory device including a substrate including a first region and a second region, a plurality of memory cells disposed in the first region and each memory cell of the plurality of memory cells spaced apart from each other, and each memory cell including a variable resistance pattern structure including a lower electrode, a magnetic tunnel junction pattern, and an upper electrode, a buried layer pattern buried between adjacent memory cells of the plurality of memory cells in the first region, the buried layer pattern including a first buried layer pattern filling a first gap between lower portions of the adjacent memory cells of the plurality of memory cells, and a second buried layer pattern filling a second gap between upper portions of the adjacent memory cells of the plurality of memory cells on the first buried layer pattern, a width of the second gap being less than a width of the first gap, and first buried layer pattern including a first material and the second buried layer pattern including a second material different than the first material, and an interlayer insulating layer pattern disposed in the second region and including the first material.

According to another aspect of the inventive concept, there is provided a variable resistance memory device including a substrate including a first region and a second region, a plurality of pad electrodes with the pad electrodes disposed apart from each other on the substrate, in the first region, a pad isolation insulating layer disposed between adjacent pad electrodes of the plurality of pad electrodes in the first region and on the substrate in the second region, variable resistance pattern structures spaced apart from each other, each disposed on a respective pad electrode of the plurality of pad electrodes in the first region, and each having a structure in which a lower electrode, a magnetic tunnel junction pattern, and an upper electrode are stacked, a buried layer pattern buried between adjacent variable resistance pattern structures in the first region, the buried layer pattern including a first buried layer pattern filling a first gap between lower portions of the adjacent variable resistance pattern structures, and a second buried layer pattern filling a second gap between upper portions of the adjacent variable resistance pattern structures on the first buried layer pattern, a width of the second gap being less than a width of the first gap, and the first buried layer pattern including a first material and the second buried layer pattern including a second material different from the first material, and an interlayer insulating layer pattern disposed in the second region and including the first material.

### BRIEF DESCRIPTION OF THE DRAWINGS

Embodiments will be more clearly understood from the following detailed description taken in conjunction with the accompanying drawings in which:

FIG. 1 is a circuit diagram illustrating a cell array of a variable resistance memory device according to an embodiment;

FIG. 2 is a circuit diagram illustrating a magnetoresistive memory cell of FIG. 1;

FIG. 3 is a perspective view of the magnetoresistive memory cell of FIG. 2;

FIGS. 4 and 5 are diagrams illustrating a write operation of a magnetic tunnel junction (MTJ) layer constituting the magnetoresistive memory cell of FIG. 1;

FIGS. 6A, 6B, 6C, 6D, and 6E are diagrams illustrating various embodiments of MTJ layers constituting the magnetoresistive memory cell of FIG. 1;

FIG. 7 is a plan view illustrating a variable resistance memory device according to an embodiment;

FIG. 8 is a cross-sectional view taken along line A-A′ of FIG. 7;

FIG. 9 is a cross-sectional view taken along line B-B′ of FIG. 7;

FIGS. 10 and 11 are partial cross-sectional views of a variable resistance memory device according to an embodiment;

FIGS. 12 and 13 are partial cross-sectional views of a variable resistance memory device according to an embodiment;

FIGS. 14 and 15 are partial cross-sectional views of a variable resistance memory device according to an embodiment;

FIGS. 16 and 17 are partial cross-sectional views of a variable resistance memory device according to an embodiment;

FIGS. 18, 19, 20, 21, 22, 23, 24, and 25 are cross-sectional views illustrating a method of manufacturing a variable resistance memory device shown in FIG. 8;

FIG. 26 is a block diagram of a variable resistance memory device according to an embodiment;

FIG. 27 is a block diagram of a data processing system including a variable resistance memory device according to an embodiment; and

FIG. 28 is a block diagram of a data processing system including a variable resistance memory device according to an embodiment.

### DETAILED DESCRIPTION OF THE EMBODIMENTS

Hereinafter, embodiments of the inventive concept will be described in detail with reference to the accompanying drawings. The inventive concept may be implemented using one of the described embodiments on its own, or the inventive concept may be implemented by combining one or more of the described embodiments. Therefore, the inventive concept is not construed as being limited to any single embodiment.

As used herein, the singular forms “a”, “an” and “the” are intended to include the plural forms as well, unless the context clearly indicates otherwise. Items described in the singular herein may be provided in plural, as can be seen, for example, in the drawings. Thus, the description of a single item that is provided in plural should be understood to be applicable to the remaining plurality of items unless context indicates otherwise. As used herein, the term “and/or” includes any and all combinations of one or more of the associated listed items and may be abbreviated as “/”.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

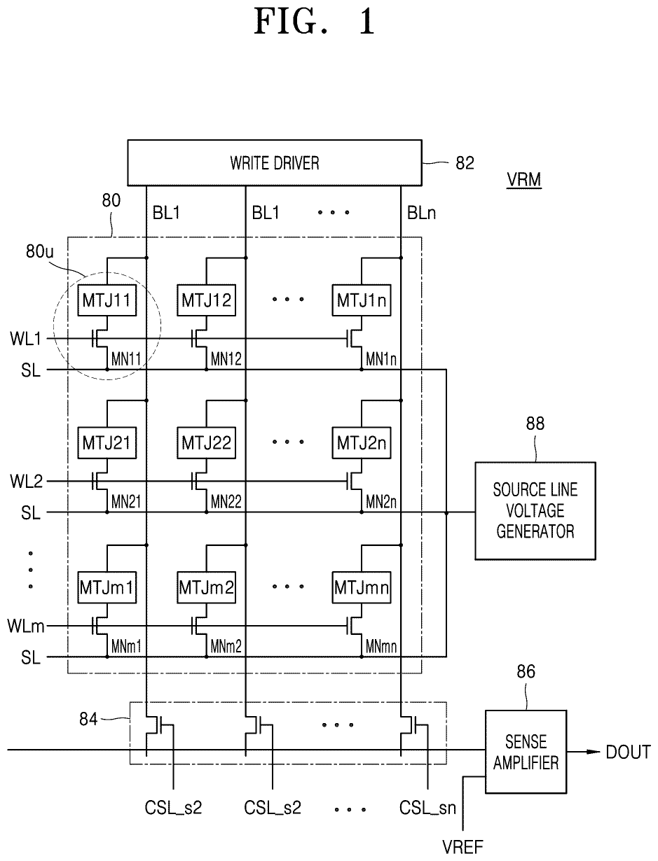

FIG. 1 is a circuit diagram illustrating a cell array of a variable resistance memory device VRM according to an embodiment.

Specifically, an example of the variable resistance memory device VRM may be a magnetoresistive memory device. The magnetoresistive memory device may be a magnetoresistive random access memory (MRAM). The variable resistance memory device VRM may include a variable resistance layer, that is, a magnetic tunnel junction (MTJ) layer.

The variable resistance memory device VRAM may include a magnetoresistive memory cell array 80. The magnetoresistive memory cell array 80 may be referred to as a memory cell array. The magnetoresistive memory cell array 80 may be connected to a write driver 82, a selection circuit 84, a source line voltage generator 88, and a sense amplifier 86.

The magnetoresistive memory cell array 80 may include a plurality of magnetoresistive memory cells 80u. The magnetoresistive memory cell 80u may be referred to as a memory cell. The magnetoresistive memory cell array 80 may include a plurality of word lines WL1 to WLm and a plurality of bit lines BL1 to BLn. The magnetoresistive memory cell array 80 may include the magnetoresistive memory cells 80u respectively between the word lines WL1 to WLm and the bit lines BL1 to BLn.

The magnetoresistive memory cell array 80 may include cell transistors MN11 to MNmn having gates respectively connected to the word lines WL1 to WLm and magnetic tunnel junction (MJT) layers MTJ11 to MTJmn respectively connected between the cell transistors MN11 to MNmn and the bit lines BL1 to BLn and constituting a variable resistance layer.

The respective sources of the cell transistors MN11 to MN1n may be coupled to a source line SL. The selection circuit 84 may selectively connect the bit lines BL1 to BLn to the sense amplifier 86 in response to column selection signals CSL_s1 to CSL_sn. The sense amplifier 86 may amplify a difference between an output voltage signal of the selection circuit 84 and a reference voltage VREF to generate output data DOUT.

The write driver 82 may be connected to the bit lines BL1 to BLn, generate a program current based on write data, and provide the program current to the bit lines BL1 to BLn. In order to magnetize the MTJ layers MTJ11 to MTJmn in the magnetoresistive memory cell array 80, a voltage higher than a voltage applied to the bit lines BL1 to BLn may be applied to the source line SL. The source line voltage generator 88 may generate a source line driving voltage VSL and provide the source line driving voltage VSL to source lines of the magnetoresistive memory cell array 80.

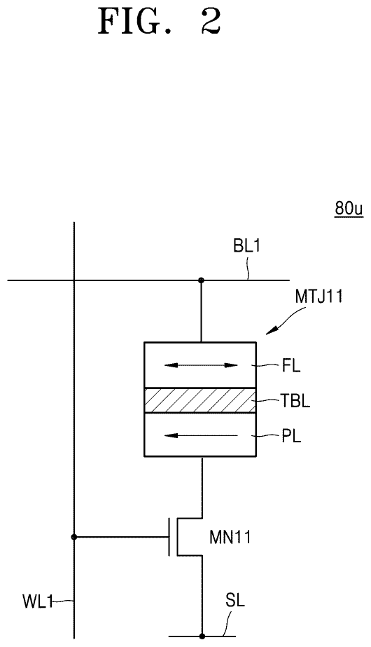

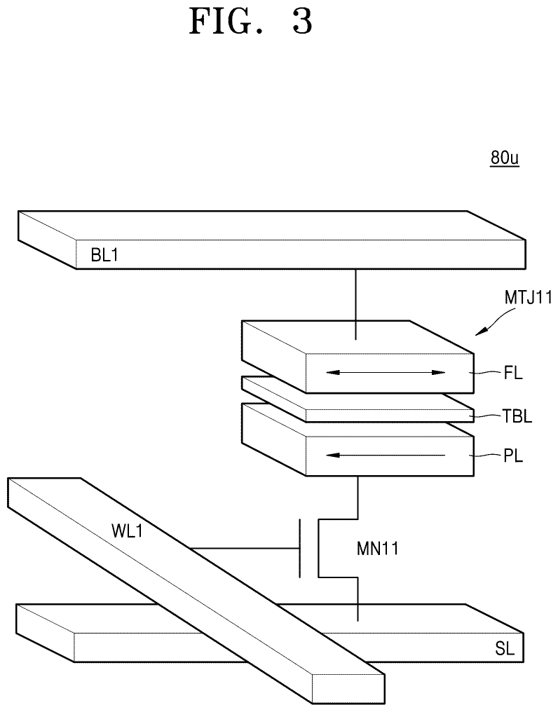

FIG. 2 is a circuit diagram illustrating the magnetoresistive memory cell 80u of FIG. 1, and FIG. 3 is a perspective view of the magnetoresistive memory cell 80u of FIG. 2.

Specifically, as shown in FIG. 2, the magnetoresistive memory cell 80u may include the cell transistor MN11, which may be an NMOS transistor, and the MTJ layer MTJ11. The cell transistor MN11 has a gate connected to the word line WL1 and a source connected to the source line SL. The MTJ layer MTJ11 is connected between a drain of the cell transistor MN11 and the bit line BL1.

As shown in FIG. 3, the MTJ layer MTJ11 may include a pinned layer PL having a pinned magnetization direction, a free layer FL magnetized in the direction of a magnetic field applied from the outside, and a tunnel barrier layer TBL provided as an insulator layer between the pinned layer PL and the free layer FL.

The MTJ layer MTJ11 of FIG. 3 may be included in a cell, which may be a part of an STT-MRAM. In order to perform a write operation of the STT-MRAM, a logic high voltage may be applied to the word line WL1 to turn on the cell transistor MN11, and a write current may be applied between the bit line BL1 and the source line SL.

In order to perform a read operation of the STT-MRAM, a logic high voltage may be applied to the word line WL1 to turn on the cell transistor MN11, and a read current may be applied from the bit line BL1 to the source line SL to determine data stored in the magnetoresistive memory cell 80u according to a resistance value of the MTJ layer MTJ11 with respect to the read current.

The resistance value of the MTJ layer MTJ11 varies depending on the magnetization direction of the free layer FL. For example, the magnetization direction of the free layer FL and the magnetization direction of the pinned layer PL may be disposed in parallel in the MTJ layer MTJ11. When the magnetizations directions are parallel, the MTJ layer MTJ11 may have a low resistance value and be read as data ‘0’. In addition, the MTJ layer MTJ11 may be disposed such that the magnetization direction of the free layer FL may be disposed in antiparallel to the degradation direction of the pinned layer PL. When the magnetization directions are not parallel, the MTJ layer MTJ11 may have a high resistance value and be read as data ‘1’.

FIGS. 2 and 3 shows a horizontal magnetic device in which the magnetization direction of the free layer FL and the magnetization direction of the pinned layer PL are horizontal, but as described below, a vertical magnetic device in which the magnetization direction of the free layer FL and the magnetization direction of the pinned layer PL are vertical may be used in another embodiment.

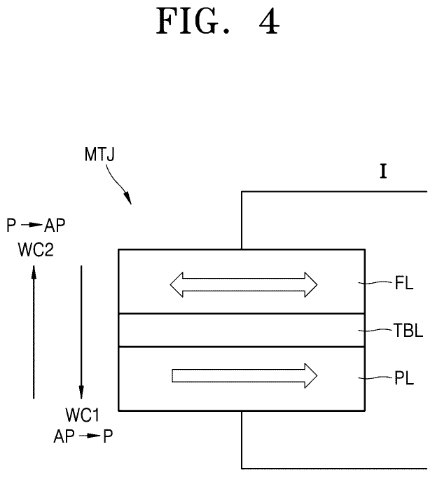

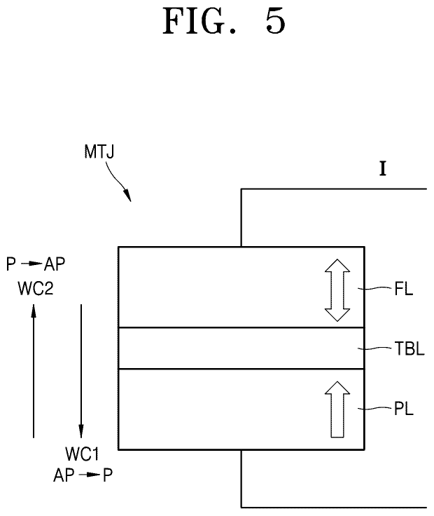

FIGS. 4 and 5 are diagrams illustrating a write operation of an MTJ layer constituting the magnetoresistive memory cell of FIG. 1.

Specifically, FIG. 4 illustrates a horizontal magnetic device in which the magnetization direction of the free layer FL and the magnetization direction of the pinned layer PL are horizontal. The MTJ layer in which the magnetization directions are horizontal may be a case in which a moving direction of current and an easy axis of magnetization are substantially vertical. FIG. 5 illustrates a case in which the magnetization direction of the free layer FL and the magnetization direction of the pinned layer PL are vertical. The MTJ layer in which the magnetization directions are vertical may be a case in which the moving direction of current and the easy axis of magnetization are substantially horizontal.

The magnetization direction of the free layer FL may be determined according to write currents WC1 and WC2 flowing through the MTJ layer. For example, when the first write current WC1 is applied, free electrons having the same spin direction as the pinned layer PL apply torque to the free layer FL. Accordingly, the free layer FL may be magnetized in parallel P to the pinned layer PL.

When the second write current WC2 is applied, electrons having a spin opposite to that of the pinned layer PL return to the free layer FL to apply torque. Accordingly, the free layer FL may be magnetized in antiparallel AP to the pinned layer PL. That is, the magnetization direction of the free layer FL in the MTJ layer may be changed by a spin transfer torque (STT).

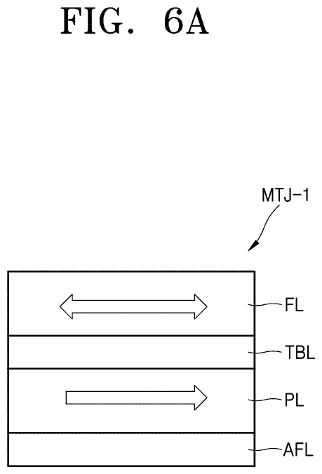

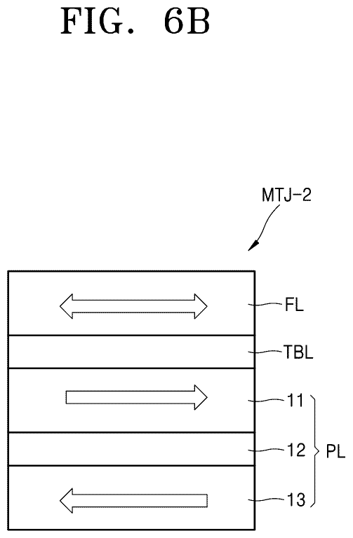

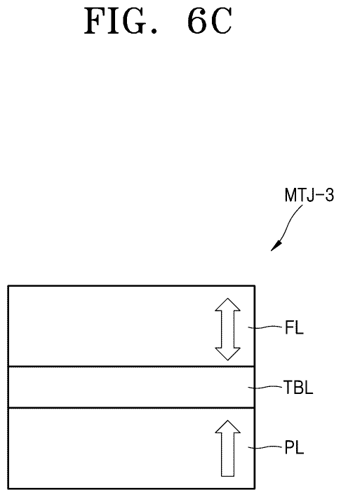

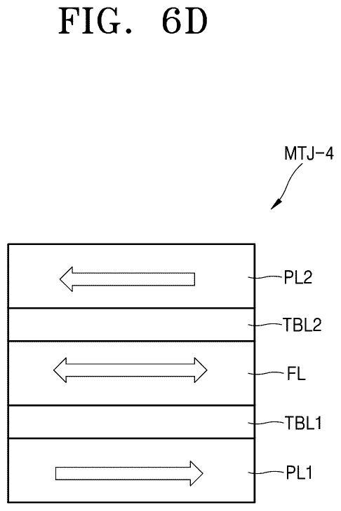

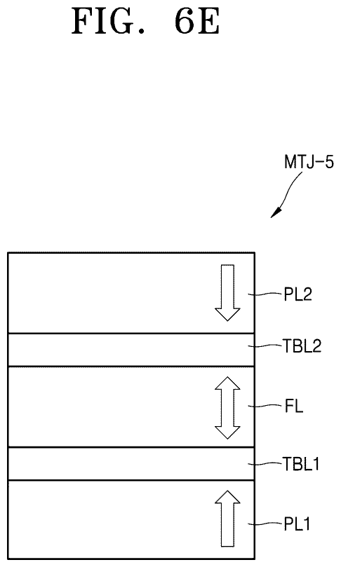

FIGS. 6A to 6E are diagrams illustrating various embodiments of MTJ layers MTJ-1 to MTJ-5 constituting the magnetoresistive memory cell of FIG. 1.

Referring to FIG. 6A, the MTJ layer MTJ-1 may include the free layer FL, the tunnel barrier layer TBL, the pinned layer PL, and an antiferromagnetic layer AFL. The MTJ layer MTJ-1 may be a single MTJ layer. The antiferromagnetic layer AFL may not be included. The free layer FL may include a material having a changeable magnetization direction.

The magnetization direction of the free layer FL may be changed by electrical/magnetic factors provided outside and/or inside the magnetoresistive memory cell. The free layer FL may include a ferromagnetic material including at least one of cobalt (Co), iron (Fe), or nickel (Ni). For example, the free layer FL may include at least one ferromagnetic material selected from FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The tunnel barrier layer TBL may have a thickness smaller than a spin diffusion distance. The tunnel barrier layer TBL may include a non-magnetic material. For example, the tunnel barrier layer TBL may include at least one non-magnetic material selected from oxides of magnesium (Mg), titanium (Ti), aluminum (Al), magnesium-zinc (MgZn), or magnesium-boron (MgB), or nitrides of titanium (Ti) or vanadium (V).

The pinned layer PL may have a magnetization direction pinned by the antiferromagnetic layer AFL. In addition, the pinned layer PL may include a ferromagnetic material. For example, the pinned layer PL may include at least one ferromagnetic material selected from CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The antiferromagnetic layer AFL may include an antiferromagnetic material. For example, the antiferromagnetic layer AFL may include at least one antiferromagnetic material selected from PtMn, IrMn, MnO, MnS, MnTe, MnF₂, FeCl₂, FeO, CoCl₂, CoO, NiCl₂, NiO, or Cr.

Referring to FIG. 6B, the pinned layer PL of the MTJ layer MTJ-2 is provided as a synthetic antiferromagnetic material (SAF). The pinned layer PL may include a first ferromagnetic layer 11, a bonding layer 12, and a second ferromagnetic layer 13. Each of the first and second ferromagnetic layers 11 and 13 may include at least one ferromagnetic material selected from CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂. In the state shown in FIG. 6B, the magnetization direction of the first ferromagnetic layer 11 and the magnetization direction of the second ferromagnetic layer 13 are different from each other and may be pinned in their respective directions. The bonding layer 12 may include ruthenium (Ru).

Referring to FIG. 6C, the MTJ layer MTJ-3 may be a single MTJ layer. In order to implement the MTJ layer MTJ-3 having a vertical magnetization direction, the free layer FL and the pinned layer PL each may include a material having high magnetic anisotropy energy. The material having high magnetic anisotropy energy may be an amorphous rare earth element alloy, and a multilayer thin film such as (Co/Pt) n or (Fe/Pt) n.

For example, the free layer FL may be an ordered alloy and may include at least one of the elements iron (Fe), cobalt (Co), nickel (Ni), palladium (Pa), or platinum (Pt). For example, the free layer FL may include at least one of a Fe—Pt alloy, a Fe—Pd alloy, a Co—Pd alloy, a Co—Pt alloy, a Fe—Ni—Pt alloy, a Co—Fe—Pt alloy, or a Co—Ni—Pt alloy. The alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt50 in a chemical quantitative expression.

The pinned layer PL may be an ordered alloy and may include at least one of the elements iron (Fe), cobalt (Co), nickel (Ni), palladium (Pa), or platinum (Pt). For example, the pinned layer PL may include at least one of a Fe—Pt alloy, a Fe—Pd alloy, a Co—Pd alloy, a Co—Pt alloy, a Co—Fe—Pt alloy, or a Co—Ni—Pt alloy. The alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt50 in the chemical quantitative expression.

FIGS. 6D and 6E show the dual MTJ layers MTJ-4 and MTJ-5. The dual MTJ layers MTJ-4 and MTJ-5 each have a structure in which a first tunnel barrier layer TBL2 and a second tunnel barrier layer TBL1 and a first pinned layer PL2 and a second pinned layer PL1 are disposed at both ends of the free layer FL, respectively.

Referring to FIG. 6D, the dual MTJ layer MTJ-4 forming horizontal magnetism may include the first pinned layer PL2, the first tunnel barrier layer TBL2, the free layer FL, the second tunnel barrier layer TBL1, and the second pinned layer PL1.

A material of each of the first pinned layer PL2, the first tunnel barrier layer TBL2, the free layer FL, the second tunnel barrier layer TBL1, and the second pinned layer PL1 may be the same as or similar to that of each of the free layer FL, the tunnel barrier layer TBL, and the pinned layer PL of FIG. 6A. When the magnetization direction of the first pinned layer PL2 and the magnetization direction of the second pinned layer PL1 are pinned in opposite directions, magnetic force by the first pinned layer PL2 and the second pinned layer PL1 is substantially offset.

Therefore, the dual MTJ layer MTJ-4 may perform a write operation by using a current less than that of the single MTJ layer MTJ-1. In addition, due to the second tunnel barrier layer TBL1, the dual MTJ layer MTJ-4 provides higher resistance during a read operation, and thus, clear data values may be obtained.

Referring to FIG. 6E, the dual MTJ layer MTJ-5 forming a vertical magnetization includes the first pinned layer PL2, the first tunnel barrier layer TBL2, the free layer FL, the second tunnel barrier layer TBL1, and the second pinned layer PL1. A material of each of the first pinned layer PL2, the first tunnel barrier layer TBL2, the free layer FL, the second tunnel barrier layer TBL1, and the second pinned layer PL1 may be the same as or similar to that of each of the free layer FL, the tunnel barrier layer TBL, and the pinned layer PL of FIG. 6C. When the magnetization direction of the first pinned layer PL2 and the magnetization direction of the second pinned layer PL1 are pinned in opposite directions, magnetic force by the first pinned layer PL2 and the second pinned layer PL1 is substantially offset. Therefore, the dual MTJ layer MTJ-5 may perform a write operation by using a current less than that of the single MTJ layer MTJ-3.

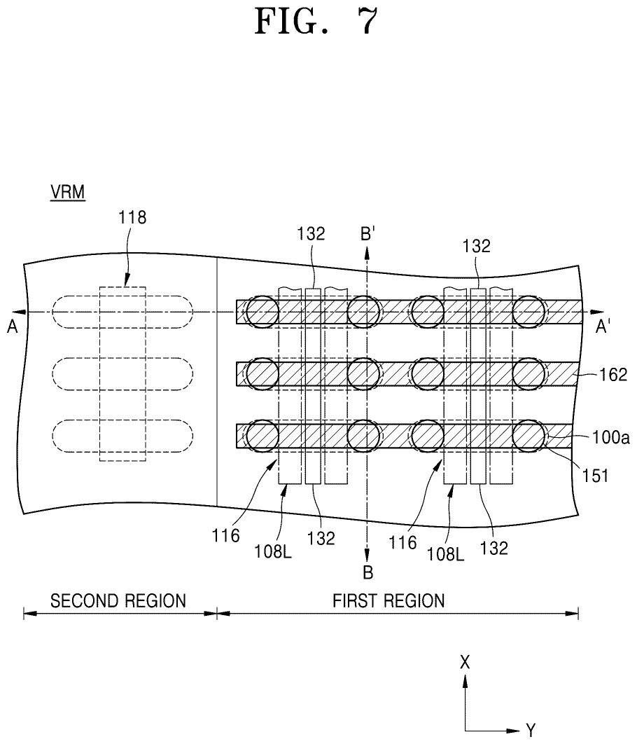

FIGS. 7 to 17 as described below detail an example of an implementation of a magnetoresistive memory device as a variable resistance memory device according to the inventive concept.

FIG. 7 is a plan view illustrating a variable resistance memory device VRAM according to an embodiment.

Specifically, the variable resistance memory device VRAM may be a magnetoresistive memory device. The variable resistance memory device VRM may include a first region and a second region. The first region may be a cell array region for forming memory cells, that is, magnetoresistive memory cells. The second region may be located in the periphery of the first region and may be a peripheral circuit region for forming core/peripheral circuits.

The first region may include active regions 100a having an isolated island shape and regularly arranged in a first direction (X direction) and a second direction (Y direction). Two first transistors 116 may be provided in each of the active regions 100a.

For example, the two first transistors 116 including two first gates 108L (or gate lines) may be provided to have a portion thereof in each of the active regions 100a. The first gate 108L may have a linear shape extending in the first direction (X direction) and may pass through multiple active regions.

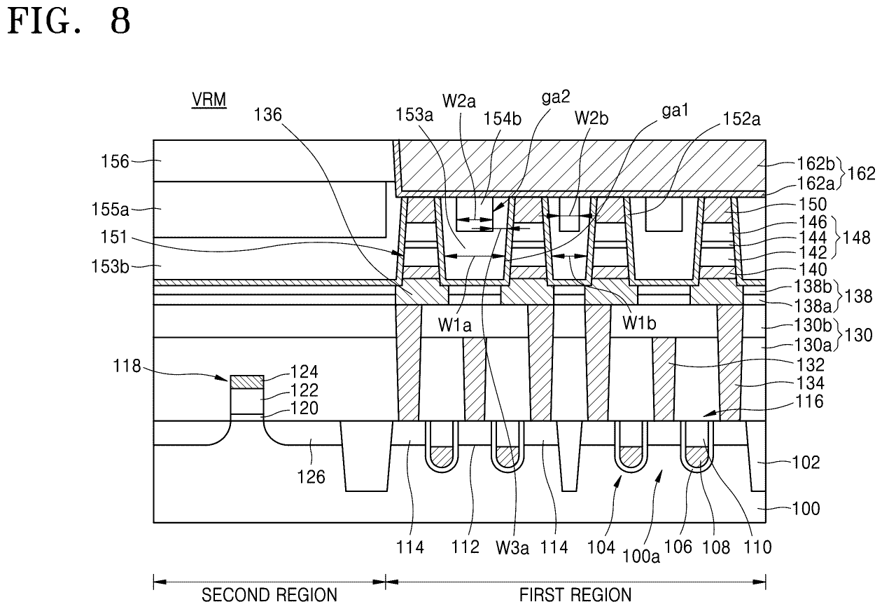

A source line 132 may extend over a central part of each of the active regions 100a while contacting a first source region 112 (FIG. 8). The source line 132 may extend in the first direction (X direction). First drain regions 114 (FIG. 8) may be located at opposing edge portions of each of the active regions 100a (e.g., outside of the area from one of the first gates 108L across the central part of the active region to the other one of the first gates 108L).

A variable resistance pattern structure 151 constituting a memory cell may be disposed on the first drain regions 114 (FIG. 8) of both edge parts of each of the active regions 100a. The variable resistance pattern structure 151 may have an isolated island shape and may be regularly arranged in the first direction (X direction) and the second direction (Y direction).

The variable resistance pattern structure 151 may include a variable resistance layer, that is, an MTJ layer or an MTJ pattern. The variable resistance pattern structure 151 may have a structure in which a lower electrode 140 (FIG. 8), an MTJ pattern 148 (FIG. 8), and an upper electrode 150 (FIG. 8) are stacked vertically as described below.

A bit line 162 that extends along an upper surface of the variable resistance pattern structure 151 while contacting the upper surface of the variable resistance pattern structure 151 may be provided on the variable resistance pattern structure 151. The bit line 162 may extend in the second direction (Y direction) perpendicular to the first direction (X direction). A plurality of bit lines 162 may be provided in parallel to each other in the second direction (Y direction).

The second region may include a second transistor 118 constituting core/peripheral circuits. The second transistor 118 may include a second gate insulating layer pattern 120 (FIG. 8), a second gate electrode 122 (FIG. 8), and a second source/drain region 126 (FIG. 8) as described below.

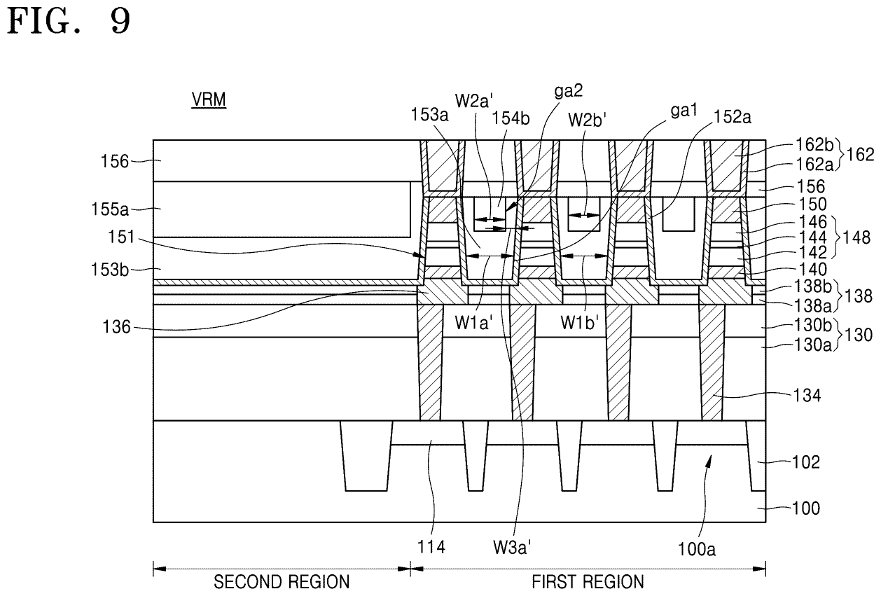

FIG. 8 is a cross-sectional view taken along line A-A′ of FIG. 7, and FIG. 9 is a cross-sectional view taken along line B-B′ of FIG. 7.

Specifically, the variable resistance memory device VRM may include a substrate 100 in which a first region and a second region are divided. As described above, the first region may be a cell array region for forming magnetoresistive memory cells. As described above, the second region may be a peripheral circuit region located in the periphery of the first region and forming core/peripheral circuits. In the substrate 100 of the first region and the second region, the active region 100a may be defined by a device isolation layer 102.

The first transistors 116 may be provided in the active region 100a of the first region. For example, the two first transistors 116 including the two first gates 108L of FIG. 7 may be provided in the active region 100a. The common first source region 112 may be provided in a central part of the active region 100a. The first drain regions 114 may be provided at both edge parts of the active region 100a.

The first transistor 116 may be a buried gate type transistor. The first gate 108L (FIG. 7) may include a first gate insulating layer pattern 106, a first gate electrode 108, and a first hardmask pattern 110 located inside a trench 104 formed in the substrate 100. As another example, the first transistor 116 may be a planar type transistor in which the first gate 108L (FIG. 7) is provided on the substrate 100.

The source line 132 contacting the first source region 112 of the active region 100a may be provided on the first source region 112. The source line 132 may include a metal such as tungsten, titanium, tantalum, etc., or a metal nitride such as tungsten nitride, titanium nitride, tantalum nitride, etc.

The second transistor 118 constituting core/peripheral circuits may be provided on the substrate 100 of the second region. The second transistor 118 may be a planar type transistor. For example, the second transistor 118 may include a second gate insulating layer pattern 120, a second gate electrode 122, and a second source/drain region 126 provided on the substrate 100 of the second region.

A first interlayer insulating layer 130 may be provided on the substrate 100 in the first region and the second region. The first interlayer insulating layer 130 may cover the source line 132, the first transistor 116, and the second transistor 118 with sufficient thicknesses (e.g., sufficient to cover the uppermost extent of the source line 132, the first transistor 116, and the second transistor 118). The first interlayer insulating layer 130 may include a first lower interlayer insulating layer 130a and a second lower interlayer insulating layer 130b. The source line 132 may extend completely through the first lower interlayer insulating layer 130a and in some examples, an upper extent of the source line 132 may be coplanar with an upper extent of the first lower interlayer insulating layer 130a and/or a lower extent of the source line 132 may be coplanar with a lower extent of the first lower interlayer insulating layer 130a.

A contact plug 134 may penetrate through the first interlayer insulating layer 130 of the first region to be in contact with the first drain region 114 may be provided. The contact plug 134 may penetrate through the first lower interlayer insulating layer 130a and the second lower interlayer insulating layer 130b. An upper surface of the contact plug 134 may be higher than an upper surface of the source line 132 (e.g., farther from the substrate in a direction perpendicular to an upper surface of the substrate).

Pad electrodes 136 may be provided on the contact plugs 134. A pad isolation insulating layer 138 may be provided between adjacent pad electrodes 136. The pad isolation insulating layer 138 may be a dual pad isolation insulating layer.

The pad isolation insulating layer 138 may include a first pad isolation insulating layer 138a provided on the second lower interlayer insulating layer 130b and a second pad isolation insulating layer 138b provided on the first pad isolation insulating layer 138a. The first pad isolation insulating layer 138a and the second pad isolation insulating layer 138b may include different materials from each other.

In some embodiments, the first pad isolation insulating layer 138a may include a material having a low dielectric constant that is lower than the dielectric constant of silicon oxide. The first pad isolation insulating layer 138a may include a material having a low dielectric constant (k value) less than 3.9, such as for example, an ultra-low-k (ULK) dielectric, a low-k (LK) dielectric, an extreme low-k (ELK) dielectric, etc.

In some embodiments, the first pad isolation insulating layer 138a may include a material such as Si, O, or C. In some embodiments, the first pad isolation insulating layer 138a may include a SiOC film, a SiOF film, a SiCH film, a SiOCH film, or a combination thereof. The second pad isolation insulating layer 138b may include a silicon oxide layer. When the first pad isolation insulating layer 138a includes a material having a low dielectric constant, parasitic capacitance between the pad electrodes 136 may be reduced.

The pad electrodes 136 may be provided when contact between the contact plug 134 and the variable resistance pattern structure 151 would be difficult. Therefore, in some embodiments, the contact plug 134 and the variable resistance pattern structure 151 may be in contact and the pad electrode 136 may not be provided.

The variable resistance pattern structure 151 constituting a memory cell may be provided on the pad electrode 136. The variable resistance pattern structure 151 may have an isolated island shape. The variable resistance pattern structure 151 may have a structure in which a lower electrode 140, an MTJ pattern 148, and an upper electrode 150 are stacked. The MTJ pattern 148 may constitute a variable resistance layer and may include a pinned layer pattern 142, a tunnel barrier layer pattern 144, and a free layer pattern 146.

The lower electrode 140 and the upper electrode 150 may include metal or metal nitride. In an embodiment, the pinned layer pattern 142 may include, for example, manganese iron (FeMn), manganese iridium (IrMn), manganese platinum (PtMn), manganese oxide (MnO), manganese sulfide (MnS), tellurium (MnTe), manganese fluoride (MnF₂), iron chloride (FeCl₂), iron oxide (FeO), cobalt chloride (CoO), nickel chloride (NiCl₂), nickel oxide (NiO), chromium (Cr), etc. A lower ferromagnetic layer (not shown), an antiferromagnetic coupling spacer layer (not shown), and an upper ferromagnetic layer (not shown) may be further included on the pinned layer pattern 142.

The upper ferromagnetic layer and the lower ferromagnetic layer may be, for example, ferromagnetic materials with each layer including at least one ferromagnetic material such as iron (Fe), nickel (Ni), or cobalt (Co). The antiferromagnetic coupling spacer layer may include, for example, at least one of ruthenium (Ru), iridium (Ir), or rhodium (Rh).

The tunnel barrier layer pattern 144 may include, for example, aluminum oxide or magnesium oxide. The free layer pattern 146 may be, for example, a ferromagnetic material including at least one of iron (Fe), nickel (Ni), or cobalt (Co).

The variable resistance pattern structure 151 is not limited to the above-described configuration, and various modified embodiments are possible. For example, in some embodiments, a lower electrode may not be provided in the variable resistance pattern structure 151.

A capping layer pattern 152a covering a sidewall of the variable resistance pattern structure 151 may be provided on an upper edge portion of the pad electrode 136 and the upper surface of the pad isolation insulating layer 138. The capping layer pattern 152a may be provided to protect the variable resistance pattern structure 151. The capping layer pattern 152a may include an insulating material. The capping layer pattern 152a may include, for example, a silicon nitride layer.

A first buried layer pattern 153a may fill a first gap ga1 between adjacent variable resistance pattern structures 151 and a second buried layer pattern 154b may fill a second gap ga2 between the adjacent variable resistance pattern structures 151. The first buried layer pattern 153a may be provided on the capping layer pattern 152a and the second buried layer pattern 154b may be provided on the first buried layer pattern 153a. The first buried layer pattern 153a and the second buried layer pattern 154b may be dual buried layer patterns.

The first buried layer pattern 153a may fill the first gap ga1 and the second buried layer pattern 154b may fill the second gap ga2. The first buried layer pattern 153a and the second buried layer pattern 154b may be completely buried in the first gap ga1 and the second gap ga2 respectively between the variable resistance pattern structures 151 without a void.

The first buried layer pattern 153a and the second buried layer pattern 154b may include different materials from each other. The second gap ga2 may be smaller than the first gap ga1. The second buried layer pattern 154b may be located in the first buried layer pattern 153a. The second buried layer pattern 154b may be buried in part of an upper portion of the first buried layer pattern 153a.

As shown in FIG. 8, the first gap ga1 may have widths W1a and W1b. The widths W1a and W1b may be different from each other. As shown in FIG. 9, the first gap ga1 may have widths W1a′ and W1b′. The widths W1a′ and W1b′ may be different from each other. In other words, the widths W1a, W1b, W1a′, and W1b′ of the first gap ga1 between the variable resistance pattern structures 151 may each be different from each other.

As shown in FIG. 8, the second gap ga2 may have widths W2a and W2b. The widths W2a and W2b may be different from each other. As shown in FIG. 9, the second gap ga2 may have widths W2a′ and W2b′. The widths W2a′ and W2b′ may be different from each other. In other words, the widths W2a, W2b, W2a′, and W2b′ of the second gap ga2 between the variable resistance pattern structures 151 may each be different from each other.

In some embodiments, as shown in FIG. 8, the width W2a of the second gap ga2 may be greater than a distance W3a from a sidewall of the second gap ga2 to a sidewall of the capping layer pattern 152a. As shown in FIG. 9, the width W2a′ of the second gap ga2 may be greater than a distance W3a′ from the sidewall of the second gap ga2 to the sidewall of the capping layer pattern 152a.

In some embodiments, as shown in FIGS. 8 and 9, a bottom surface of the second buried layer pattern 154b may be located at a height that is lower than an upper surface of the free layer pattern 146 or a bottom surface of the upper electrode 150 in a vertical direction.

A second buried layer pattern 154b may be provided only in the first region of the substrate 100 and may not be provided in the second region. The second buried layer pattern 154b and the variable resistance pattern structure 151 may each have a flat upper surface. The first buried layer pattern 153a may include an insulating material having a good step coverage and easily filling the first gap ga1 between the variable resistance pattern structures 151.

In some embodiments, the first buried layer pattern 153a may include a material having a low dielectric constant that is lower than that of silicon oxide. The first buried layer pattern 153a may include a material having a low dielectric constant (k value) that is less than 3.9, for example, an ULK dielectric, an LK dielectric, an ELK dielectric, etc.

In some embodiments, the first buried layer pattern 153a may include a material such as Si, O, or C. In some embodiments, the first buried layer pattern 153a may include a SiOC film, a SiOF film, a SiCH film, a SiOCH film, or a combination thereof.

When the first buried layer pattern 153a includes a material having a low dielectric constant, parasitic capacitance between the variable resistance pattern structures 151 may be reduced. The second buried layer pattern 154b may include a silicon oxide layer. The silicon oxide layer may be deposited by an atomic layer lamination method.

The bit line 162 that extends along an upper surface of the variable resistance pattern structure 151 while contacting the upper surfaces of the variable resistance pattern structures 151 may be provided on the first buried layer pattern 153a, the second buried layer pattern 154b, and the variable resistance pattern structure 151. The bit line 162 may be in contact with the upper electrode 150 of the variable resistance pattern structure 151.

The bit line 162 may have a structure in which a barrier metal layer 162a and a metal layer 162b are stacked. The barrier metal layer 162a may include titanium, titanium nitride, tantalum, tantalum nitride, etc. The metal layer 162b may include copper, tungsten, aluminum, etc.

The variable resistance pattern structure 151 may be provided on the first interlayer insulating layer 130 in the first region, and the variable resistance pattern structure 151 may not be provided on the first interlayer insulating layer 130 in the second region. The first region and the second region may have a step difference in height due to the variable resistance pattern structure 151. The first region may be an upper end region, and the second region may be a lower end region.

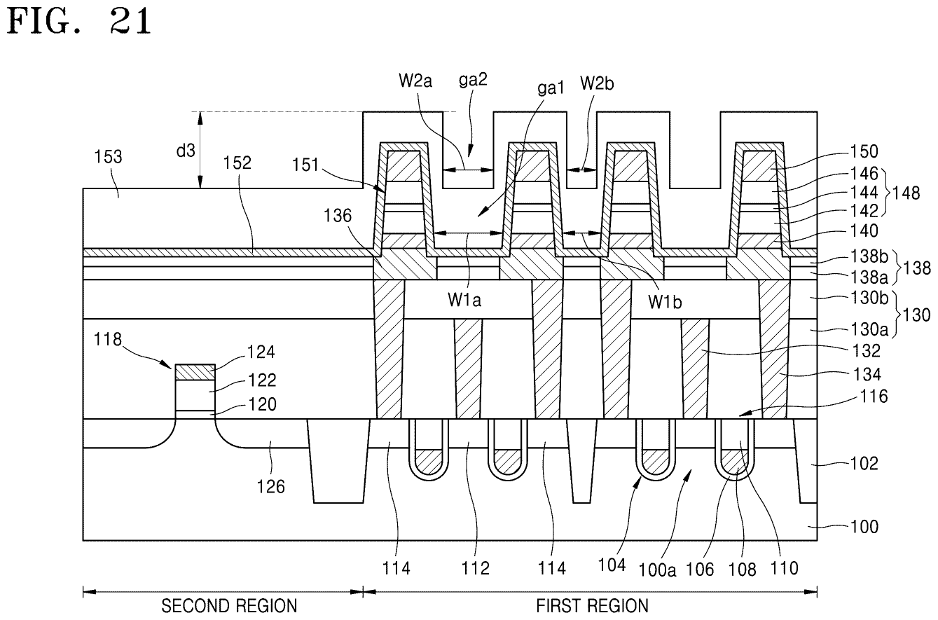

A second interlayer insulating layer pattern 153b, which may be formed from the first buried layer 153 (see FIG. 21), a third interlayer insulating layer pattern 155a, and a fourth interlayer insulating layer pattern 156 may be sequentially provided on the capping layer pattern 152a in the second region. The second interlayer insulating layer pattern 153b and the third interlayer insulating layer pattern 155a may be buried in the lower end region of the second region to offset the step difference between the first region and the second region.

The second interlayer insulating layer pattern 153b may be a lower interlayer insulating layer pattern formed to have a thickness corresponding to that of the first buried layer pattern 153a. The second interlayer insulating layer pattern 153b and the first buried layer pattern 153a may have the same body (e.g., may be a single homogenous structure and/or may have originally been the same layer before patterning). The third interlayer insulating layer pattern 155a may be an upper interlayer insulating layer pattern formed to have a thickness corresponding to that of the second buried layer pattern 154b.

The second interlayer insulating layer pattern 153b and the third interlayer insulating layer pattern 155a may include the same material as the first buried layer pattern 153a. The second interlayer insulating layer pattern 153b and the third interlayer insulating layer pattern 155a may include that material having a low dielectric constant that is used for the first buried layer pattern 153a.

The second interlayer insulating layer pattern 153b and the third interlayer insulating layer pattern 155a may include a material having a low dielectric constant that is lower than that of silicon oxide. The third interlayer insulating layer pattern 155a may include a material that insulates the bit line 162. In some embodiments, the third interlayer insulating layer pattern 155a may include a silicon oxide layer. In the first region, the third interlayer insulating layer pattern 155a may be provided between the bit lines 162.

As such, the variable resistance memory device VRM includes the first buried layer pattern 153a and the second buried layer pattern 154b that completely fill the first gap ga1 and the second gap ga2 between the variable resistance pattern structures 151. Accordingly, the variable resistance memory device VRM may suppress the occurrence of voids between the variable resistance pattern structures 151.

As a result, the variable resistance memory device VRM may significantly improve reliability by improving insulation performance between the variable resistance pattern structures 151 and reducing contact defects between the variable resistance pattern structures 151 and the bit line 162.

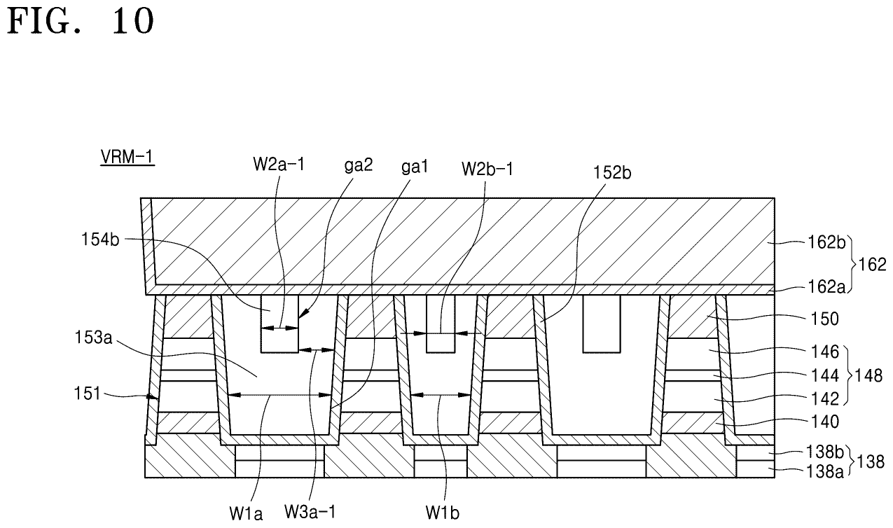

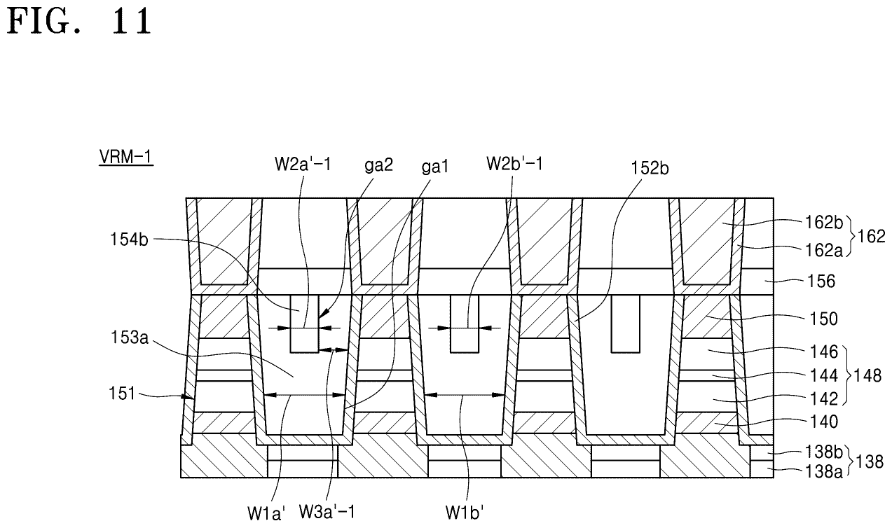

FIGS. 10 and 11 are partial cross-sectional views of a variable resistance memory device VRM-1 according to an embodiment.

Specifically, FIG. 10 is a partial cross-sectional view taken along line A-A′ of FIG. 7. FIG. 11 is a partial cross-sectional view taken along line B-B′ of FIG. 7. FIGS. 10 and 11 may be partial cross-sectional views corresponding to FIGS. 8 and 9, respectively.

The variable resistance memory device VRM-1 may be the same as the variable resistance memory device VRM of FIGS. 7 to 9, except that the size of the second gap ga2 formed in the second buried layer pattern 154b is different. In FIGS. 10 and 11, descriptions of elements that were described previously with reference to FIGS. 7 to 9 may be briefly described or omitted.

In the variable resistance memory device VRM-1, the first buried layer pattern 153a and the second buried layer pattern 154b respectively filling the first gap ga1 and the second gap ga2 between the variable resistance pattern structures 151 may be formed. The first buried layer pattern 153a may fill the first gap ga1 and the second buried layer pattern 154b may fill the second gap ga2.

As shown in FIG. 10, in the variable resistance memory device VRM-1, the second gap ga2 formed in the second buried layer pattern 154b may have widths W2a-1 and W2b-1. The widths W2a-1 and W2b-1 may be respectively less than the widths W2a and W2b shown in FIG. 8. The widths W2a-1 and W2b-1 may be different from each other. As shown in FIG. 10, the width W2a-1 of the second gap ga2 formed in the second buried layer pattern 154b may be less than or equal to a distance W3a-1 from a sidewall of the second gap ga2 to a sidewall of the capping layer pattern 152a.

As shown in FIG. 11, in the variable resistance memory device VRM-1, the second gap ga2 formed in the second buried layer pattern 154b may have widths W2a′-1 and W2b′-1. The widths W2a′-1 and W2b′-1 may be respectively less than the widths W2a′ and W2b′ shown in FIG. 9. The widths W2a′-1 and W2b′-1 may be different from each other. As shown in FIG. 11, the width W2a′-1 of the second gap ga2 formed in the second buried layer pattern 154b may be less than or equal to a distance W3a′-1 from the sidewall of the second gap ga2 to the sidewall of the capping layer pattern 152a.

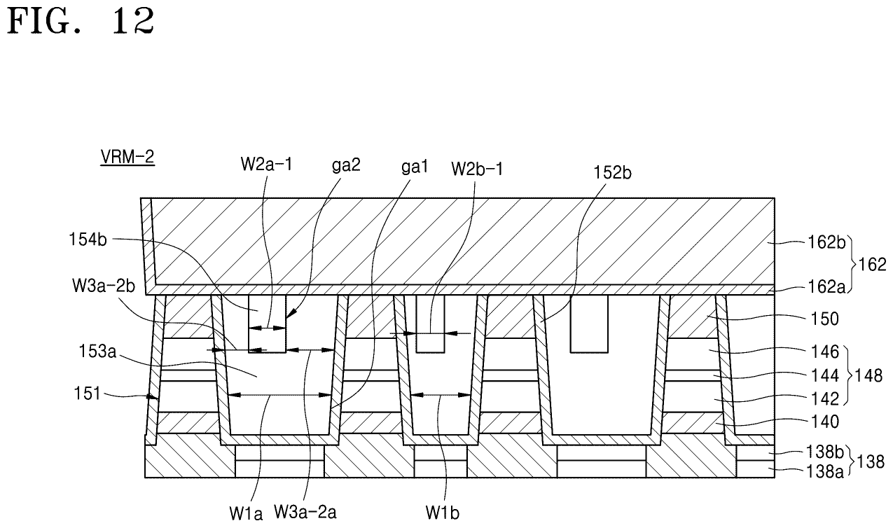

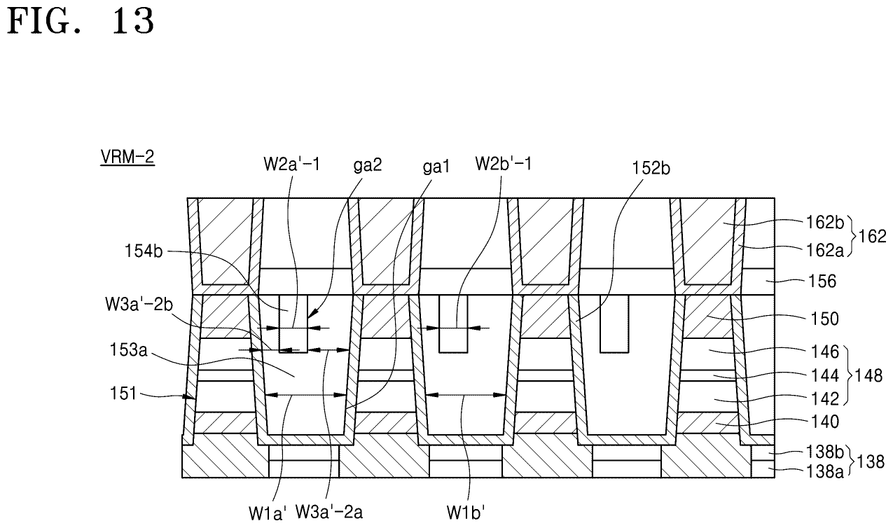

FIGS. 12 and 13 are partial cross-sectional views of a variable resistance memory device VRM-2 according to an embodiment.

Specifically, FIG. 12 is a partial cross-sectional view taken along line A-A′ of FIG. 7. FIG. 13 is a partial cross-sectional view taken along line B-B′ of FIG. 7. FIGS. 12 and 13 may be partial cross-sectional views corresponding to FIGS. 8 and 9, respectively.

The variable resistance memory device VRM-2 may be the same as the variable resistance memory device VRM of FIGS. 7 to 9, except that the second gap ga2 formed in the second buried layer pattern 154b is formed at a different position. In FIGS. 12 and 13, descriptions of elements described previously with reference to FIGS. 7 to 9 may be briefly described or omitted.

In the variable resistance memory device VRM-2, the first buried layer pattern 153a and the second buried layer pattern 154b respectively filling the first gap ga1 and the second gap ga2 between the variable resistance pattern structures 151 may be formed. The first buried layer pattern 153a may fill the first gap ga1 and the second buried layer pattern 154b may fill the second gap ga2.

As shown in FIG. 12, in the variable resistance memory device VRM-2, the second gap ga2 formed in the second buried layer pattern 154b may have the widths W2a-1 and W2b-1. The widths W2a-1 and W2b-1 may be respectively less than the widths W2a and W2b shown in FIG. 8. The widths W2a-1 and W2b-1 may be different from each other.

In addition, the second gap ga2 may be disposed to be biased to one side, for example, the left side, in the first buried layer pattern 153a. The second buried layer pattern 154b may be disposed to be biased to one side relative to the center of the first buried layer pattern 153a.

In this case, as shown in FIG. 12, the width W2a-1 of the second gap ga2 formed in the second buried layer pattern 154b may be less than a distance W3a-2a from a right sidewall of the second gap ga2 to a sidewall of the capping layer pattern 152a. The width W2a-1 of the second gap ga2 formed in the second buried layer pattern 154b may be greater than a distance W3a-2b from a left sidewall of the second gap Ga2 to the sidewall of the capping layer pattern 152a. The distance W3a-2a may be different from the distance W3a-2b. The distance W3a-2a may be greater than the distance W3a-2b.

In some embodiments, unlike FIG. 12, the second gap ga2 may be disposed to be biased to one side, for example, the right side, in the first buried layer pattern 153a. In this case, the distance W3a-2a may be less than the distance W3a-2b.

As shown in FIG. 13, in the variable resistance memory device VRM-2, the second gap ga2 formed in the second buried layer pattern 154b may have the widths W2a′-1 and W2b′-1. The widths W2a′-1 and W2b′-1 may be respectively less than the widths W2a′ and W2b′ shown in FIG. 9. The widths W2a′-1 and W2b′-1 may be different from each other.

In addition, the second gap ga2 may be disposed to be biased to one side, for example, the left side, in the first buried layer pattern 153a. The second buried layer pattern 154b may be disposed to be biased to one side relative to the center of the first buried layer pattern 153a.

In this case, as shown in FIG. 13, the width W2a′-1 of the second gap ga2 formed in the second buried layer pattern 154b may be less than a distance W3a′-2a from the right sidewall of the second gap ga2 to the sidewall of the capping layer pattern 152a. The width W2a-1 of the second gap ga2 formed in the second buried layer pattern 154b may be greater than a distance W3a′-2b from the left wall of the second gap ga2 to the sidewall of the capping layer pattern 152a. The distance W3a′-2a may be different from the distance W3a′-2b. The distance W3a′-2a may be greater than the distance W3a′-2b.

In some embodiments, unlike FIG. 13, the second gap ga2 may be disposed to be biased to one side, for example, the right side, in the first buried layer pattern 153a. In this case, the distance W3a′-2a may be less than the distance W3a′-2b.

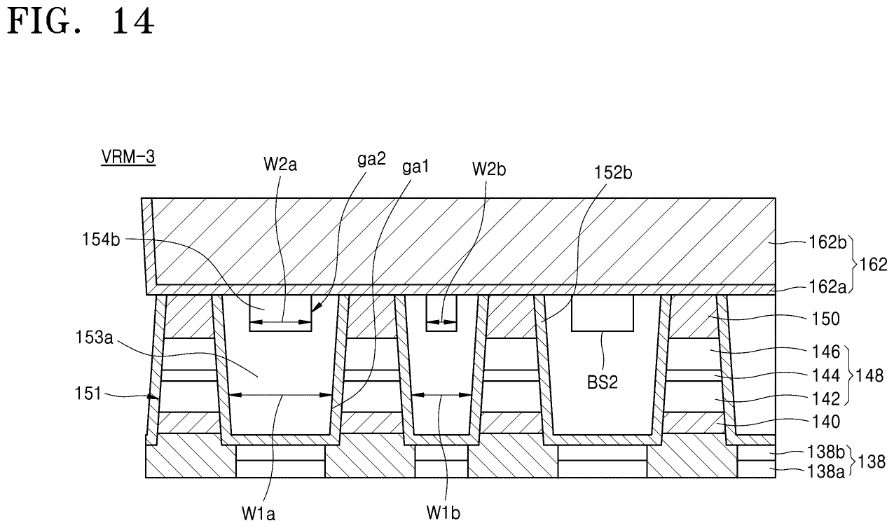

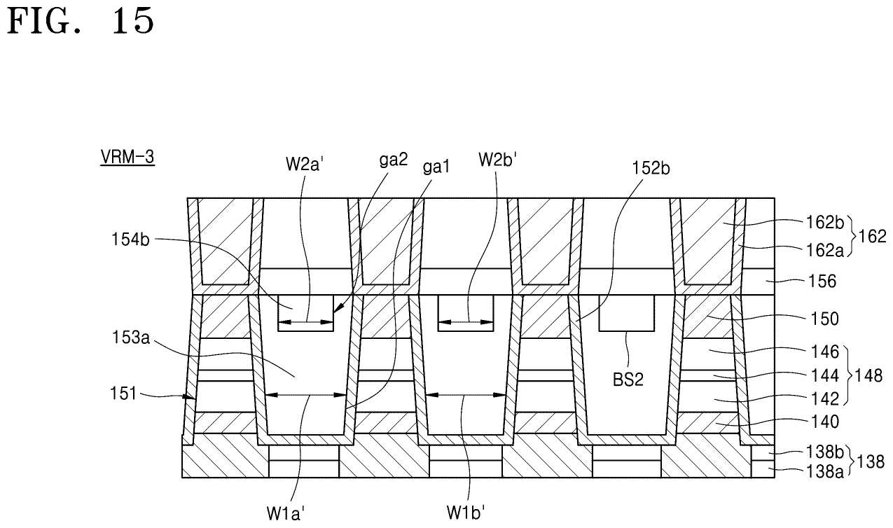

FIGS. 14 and 15 are partial cross-sectional views of a variable resistance memory device VRM-3 according to an embodiment.

Specifically, FIG. 14 is a partial cross-sectional view taken along line A-A′ of FIG. 7. FIG. 15 is a partial cross-sectional view taken along line B-B′ of FIG. 7. FIGS. 14 and 15 may be partial cross-sectional views corresponding to FIGS. 8 and 9, respectively.

The variable resistance memory device VRM-3 may be the same as the variable resistance memory device VRM of FIGS. 7 to 9, except that a position of the bottom surface BS2 of the second buried layer pattern 154b is different. In FIGS. 14 and 15, descriptions of elements previously given with reference to FIGS. 7 to 9 may be briefly described or omitted.

In the variable resistance memory device VRM-3, the first buried layer pattern 153a and the second buried layer pattern 154b respectively filling the first gap ga1 and the second gap ga2 between the variable resistance pattern structures 151 may be provided. The first buried layer pattern 153a may fill the first gap ga1 and the second buried layer pattern 154b may fill the second gap ga2.

As shown in FIGS. 14 and 15, in the variable resistance memory device VRM-3, the bottom surface BS2 of the second buried layer pattern 154b may be at a height that is the same as or higher than an upper surface of the free layer pattern 146 or a bottom surface of the upper electrode 150 in a vertical direction. The bottom surface BS2 of the second gap ga2 formed in the first buried layer pattern 153a may be at a height that is the same as or higher than the upper surface of the free layer pattern 146 or the bottom surface of the upper electrode 150 in the vertical direction.

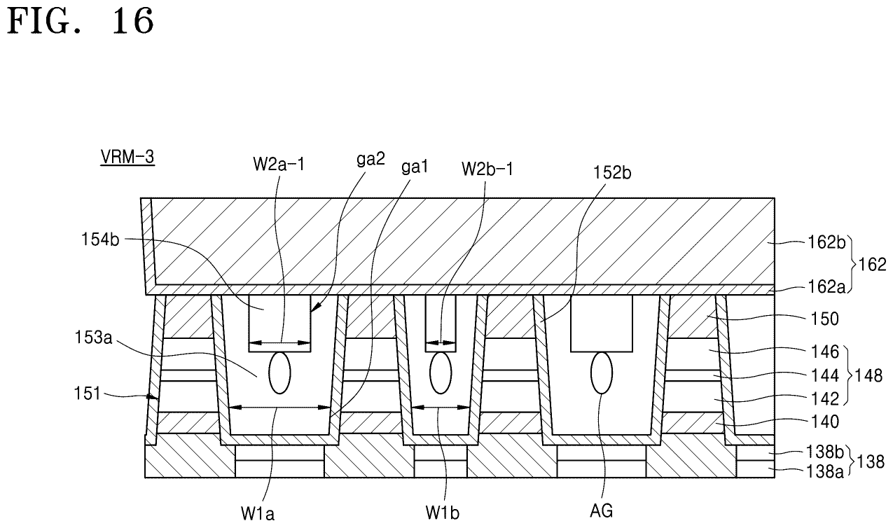

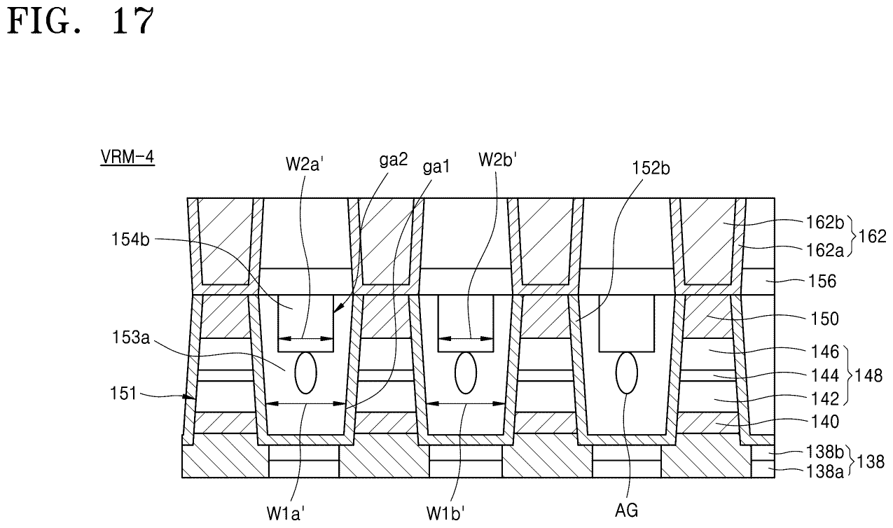

FIGS. 16 and 17 are partial cross-sectional views of a variable resistance memory device VRM-4 according to an embodiment.

Specifically, FIG. 16 is a partial cross-sectional view taken along line A-A′ of FIG. 7. FIG. 17 is a partial cross-sectional view taken along line B-B′ of FIG. 7. FIGS. 16 and 17 may be partial cross-sectional views corresponding to FIGS. 8 and 9, respectively.

The variable resistance memory device VRM-4 may be the same as the variable resistance memory device VRM of FIGS. 7 to 9, except that an air gap AG is further formed in the first buried layer pattern 153a. In FIGS. 16 and 17, descriptions of elements previously given with reference to FIGS. 7 to 9 may be briefly described or omitted. It should be appreciated that an “air gap” may comprise a gap having air or other gases (e.g., such as those present during manufacturing) or may comprise a gap forming a vacuum therein. The term “air” as discussed herein, may refer to atmospheric air, or other gases that may be present during the manufacturing process.

In the variable resistance memory device VRM-4, the first buried layer pattern 153a and the second buried layer pattern 154b respectively filling the first gap ga1 and the second gap ga2 between the variable resistance pattern structures 151 may be provided. The first buried layer pattern 153a may fill the first gap ga1 and the second buried layer pattern 154b may fill the second gap ga2.

As shown in FIGS. 16 and 17, in the variable resistance memory device VRM-4, the air gap AG may be formed in the first buried layer pattern 153a. The air gap AG may be formed on a lower portion of the second buried layer pattern 154b. The air gap AG may be formed between the second buried layer pattern 154b and the first buried layer pattern 153a in the vertical direction.

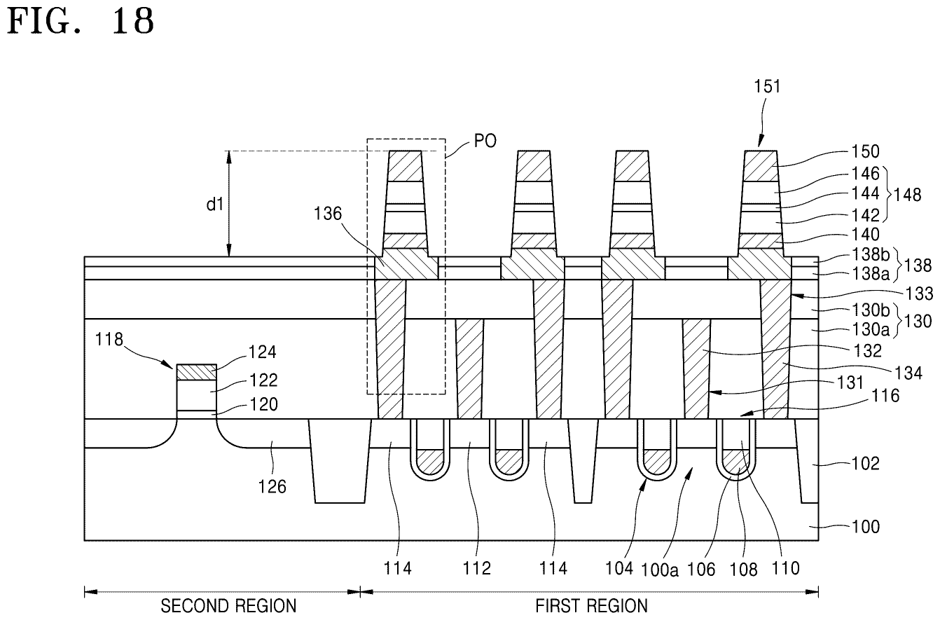

FIGS. 18 to 25 are cross-sectional views illustrating a method of manufacturing a variable resistance memory device shown in FIG. 8.

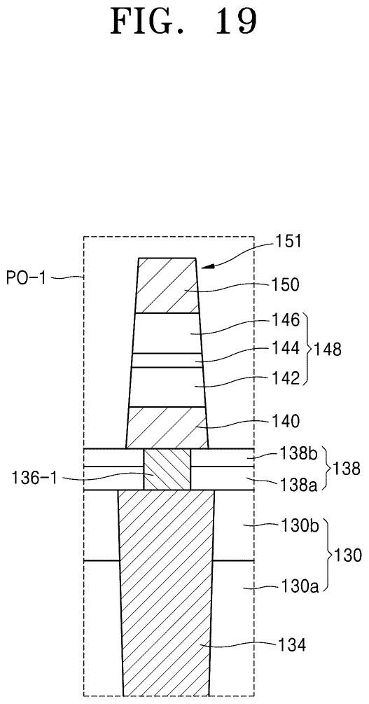

Referring to FIGS. 18 and 19, the active region 100a of the substrate 100 is defined by forming the device isolation layer 102 on the substrate 100 (e.g., active regions of the substrate may be defined by the placement of the device isolation layer 102). The substrate 100 may be divided into a first region (or cell array region) in which variable resistance memory cells (or memory cells) are formed and a second region (or peripheral circuit region) in which core/peripheral circuits are formed. The device isolation layer 102 may be formed through a shallow trench isolation (STI) process.

The first transistor 116 is formed on the substrate 100 of the first region. The two first transistors 116 may be formed in the active region 100a. For example, the first transistors 116 may be buried gate type transistors.

In order to form the first transistors 116, a mask pattern is formed on the substrate 100, and the trench 104 is formed by etching the substrate 100 by using the mask pattern. Two trenches 104 may be formed in one active region 100a. The first gate 108L (FIG. 7) including the first gate insulating layer pattern 106, the first gate electrode 108, and the first hardmask pattern 110 is formed in the trench 104.

In addition, the first source region 112 and the first drain region 114 are respectively formed by injecting impurities into the active regions 100a on both sides of the first gate electrode 108 constituting the first gate 108L (FIG. 7). The first source region 112 may be provided as a common source region in the two first transistors 116. In the embodiment, the first transistor 116 is described as a buried gate type transistor, but is not limited thereto. For example, the first transistor 116 may be a planar gate type transistor.

The second transistor 118 included in the core/peripheral circuit is formed on the substrate 100 of the second region. For example, the second transistor 118 may be a planar gate type transistor. In order to form the second transistor 118, a second gate insulating layer and a second gate electrode layer are formed on the substrate 100.

The second gate insulating layer pattern 120 and the second gate electrode 122 are formed by etching the second gate insulating layer and the second gate electrode layer by using a second hardmask pattern 124. In addition, a second source/drain region 126 is formed by injecting impurities into the active regions 100a on both sides of the second gate electrode 122.

Subsequently, a first lower interlayer insulating layer 130a covering the first transistor 116 and the second transistor 118 is formed on the substrate 100 in the first region and the second region. Thereafter, a planarization process may be performed such that an upper surface of the first lower interlayer insulating layer 130a is planarized.

The planarization process may include a chemical mechanical polishing process or an etch-back process. A first opening 131 exposing the surface of the first source region 112 is formed by etching a part of the first lower interlayer insulating layer 130a of the first region.

The source line 132 in contact with the first source region 112A is formed by forming and planarizing a first conductive layer in the first opening 131. The source line 132 may be formed to include at least one of, for example, metal such as tungsten, titanium, and tantalum, or metal nitride such as tungsten nitride, titanium nitride, or tantalum nitride.

A second lower interlayer insulating layer 130b is formed on the first lower interlayer insulating layer 130a and the source line 132. The upper surface of the first lower interlayer insulating layer 130a is planar, and thus, the second lower interlayer insulating layer 130b may also have a flat upper surface. The first lower interlayer insulating layer 130a and the second lower interlayer insulating layer 130b each may include silicon oxide.

Second openings 133 penetrating the first lower interlayer insulating layer 130a and the second lower interlayer insulating layer 130b of the first region and exposing the first drain region 114 are formed. The contact plug 134 in contact with the first drain region 114A is formed by forming and planarizing a second conductive layer in the second opening 133. The contact plug 134 may include at least one of, for example, metal such as tungsten, titanium, and tantalum, or metal nitride such as tungsten nitride, titanium nitride, or tantalum nitride.

The first interlayer insulating layer 130 including the first lower interlayer insulating layer 130a and the second lower interlayer insulating layer 130b is formed on the substrate 100 of the first region and the second region. The contact plug 134 and the source line 132 are formed in the first interlayer insulating layer 130 of the first region. An upper surface of the contact plug 134 may be located higher than an upper surface of the source line 132.

Subsequently, a pad layer is formed on the first interlayer insulating layer 130. The pad layer may include at least one metal such as tungsten, titanium, and tantalum, or metal nitride such as tungsten nitride, titanium nitride, or tantalum nitride. The pad electrodes 136 in contact with the contact plugs 134 are formed by etching the pad layer.

In some embodiments, as shown in PO of FIG. 18, each of the pad electrodes 136 may be disposed to be biased toward one side from the center of the contact plug 134. In some embodiments, as shown in PO-1 of FIG. 19, each of pad electrodes 136-1 may be disposed in the center of the contact plug 134.

The pad isolation insulating layer 138 filling a space between the pad electrodes 136 is formed. The pad isolation insulating layer 138 may include the first pad isolation insulating layer 138a formed on the second lower interlayer insulating layer 130b and the second pad isolation insulating layer 138b formed on the first pad isolation insulating layer 138a.

Subsequently, the variable resistance pattern structures 151 in contact with the pad electrodes 136 are formed. Due to the variable resistance pattern structure 151, the first region and the second region may have a step difference of d1 (i.e., a step height). The step difference d1 may be a distance between an uppermost surface of the variable resistance pattern structure 151 and an uppermost surface of the pad isolation insulating layer 138.

The variable resistance pattern structure 151 may constitute a memory cell as described above. The variable resistance pattern structure 151 may include the lower electrode 140, the MTJ pattern 148, and the upper electrode 150, and may have a structure in which the lower electrode 140, the MTJ pattern 148, and the upper electrode 150 are stacked. The MTJ pattern 148 may include the pinned layer pattern 142, the tunnel barrier layer pattern 144, and the free layer pattern 146, which are sequentially stacked.

In some embodiments, as shown in PO of FIG. 18, the width of the variable resistance pattern structure 151 may be less than the width of each of the pad electrodes 136. In some embodiments, as shown in PO-1 of FIG. 19, the width of the variable resistance pattern structure 151 may be greater than the width of each of the pad electrodes 136-1.

Here, a process of forming the variable resistance pattern structure 151 is described in detail. A lower electrode layer, a pinned layer, a tunnel barrier layer, a free layer, and an upper electrode layer are sequentially formed on the pad electrodes 136 and the pad isolation insulating layer 138, and the upper electrode 150 is formed by patterning the upper electrode layer through a photo etching process. Thereafter, the variable resistance pattern structures 151 in contact with each pad electrodes 136 may be formed by patterning the free layer, the tunnel barrier layer, the pinned layer, and the lower electrode layer through a dry etching process using the upper electrode 150 as an etching mask.

The lower electrode layer and the upper electrode layer may be formed using metal or metal nitride. In an embodiment, a lower ferromagnetic layer, an antiferromagnetic coupling spacer layer, and an upper ferromagnetic layer may be further included on the pinned layer. The pinned layer may be formed using, for example, manganese iron (FeMn), manganese iridium (IrMn), manganese platinum (PtMn), manganese oxide (MnO), manganese sulfide (MnS), tellurite (MnTe), manganese fluoride (MnF₂), iron chloride (FeCl₂), iron oxide (FeO), cobalt chloride (CoCl₂), cobalt oxide (CoO), nickel chloride (NiO), chromium (Cr), etc. The upper ferromagnetic layer and the lower ferromagnetic layer may be formed using, for example, a ferromagnetic material including at least one ferromagnetic material such as iron (Fe), nickel (Ni), or cobalt (Co). The antiferromagnetic coupling spacer layer may be formed using, for example, at least one of ruthenium (Ru), iridium (Ir), or rhodium (Rh).

In addition, the tunnel barrier layer may be formed using, for example, aluminum oxide or magnesium oxide. The free layer may be formed using, for example, a ferromagnetic material including at least one ferromagnetic material such as iron (Fe), nickel (Ni), or cobalt (Co). The configuration of the variable resistance pattern structures 151 is not limited to the configuration described above, and various modified embodiments are possible.

The variable resistance pattern structures 151 are formed only in the first region of the substrate 100. Therefore, the lower electrode layer, the pinned layer, the tunnel barrier layer, the free layer, and the upper electrode layer formed in the second region of the substrate 100 may all be removed in an etching process.

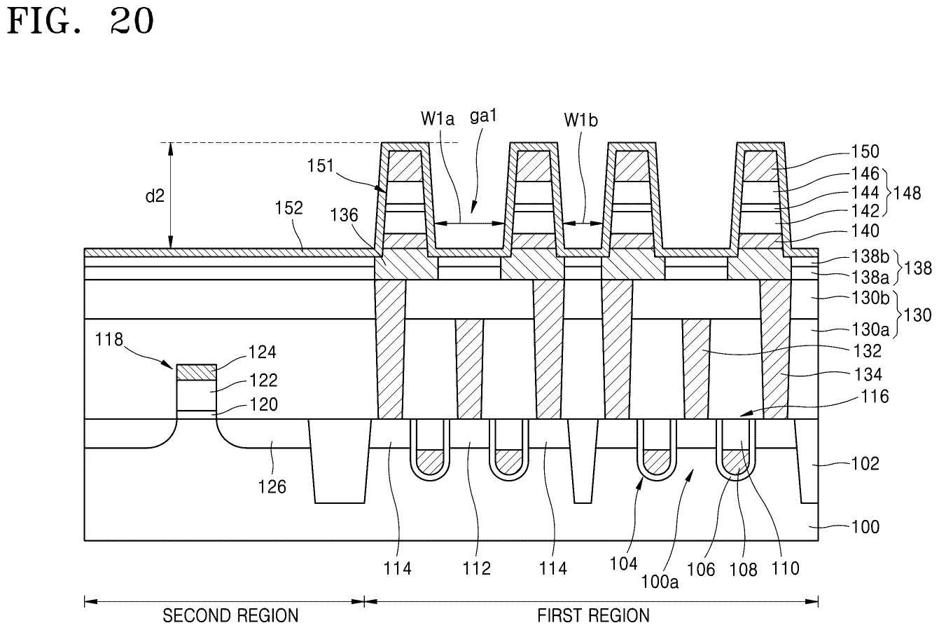

Referring to FIG. 20, a capping layer 152 is formed on the first interlayer insulating layer 130, the variable resistance pattern structures 151, the pad isolation insulating layer 138, and the pad electrodes 136. The capping layer 152 may be formed along surfaces of the variable resistance pattern structures 151 in the first region. The capping layer 152 may be formed not to fill between the variable resistance pattern structures 151 in the first region.

The capping layer 152 may include an insulating material layer. The capping layer 152 may include silicon nitride, etc. The capping layer 152 may be formed on the surfaces of the variable resistance pattern structures 151 and, thus, may be provided as a protective layer for protecting the variable resistance pattern structures 151 in a subsequent process. In some embodiments, the capping layer 152 may not be formed when it is not needed.

After the capping layer 152 is formed, the first gap ga1 may be formed between the variable resistance pattern structures 151 in the first region. The first gap ga1 may have the widths W1a and W1b. The widths W1a and W1b may be different from each other.

Due to the variable resistance pattern structure 151 and the capping layer 152, the first region and the second region may have a step difference of d2. The step difference d2 may be a distance between an uppermost surface of the capping layer 152 on the variable resistance pattern structure 151 and an uppermost surface of the capping layer 152 on the pad isolation insulating layer 138.

Referring to FIG. 21, a first buried layer 153 is formed using an insulating material to partially fill the first gap ga1 between the variable resistance pattern structures 151 on the capping layer 152. The first buried layer 153 may include a material having a low dielectric constant that is lower than that of a silicon oxide.

Accordingly, the second gap ga2 is formed in the first buried layer 153 between the variable resistance pattern structures 151. The second gap ga2 may be smaller than the first gap ga1. The second gap ga2 may have the widths W2a and W2b. The widths W2a and W2b may be different from each other.

Due to the variable resistance pattern structure 151, the capping layer 152, and the first buried layer 153, the first region and the second region may have a step difference of d3. The step difference d3 may be a distance between the uppermost surface of the first buried layer 153 on the variable resistance pattern structure 151 and the uppermost surface of the first buried layer 153 on the pad isolation insulating layer 138.

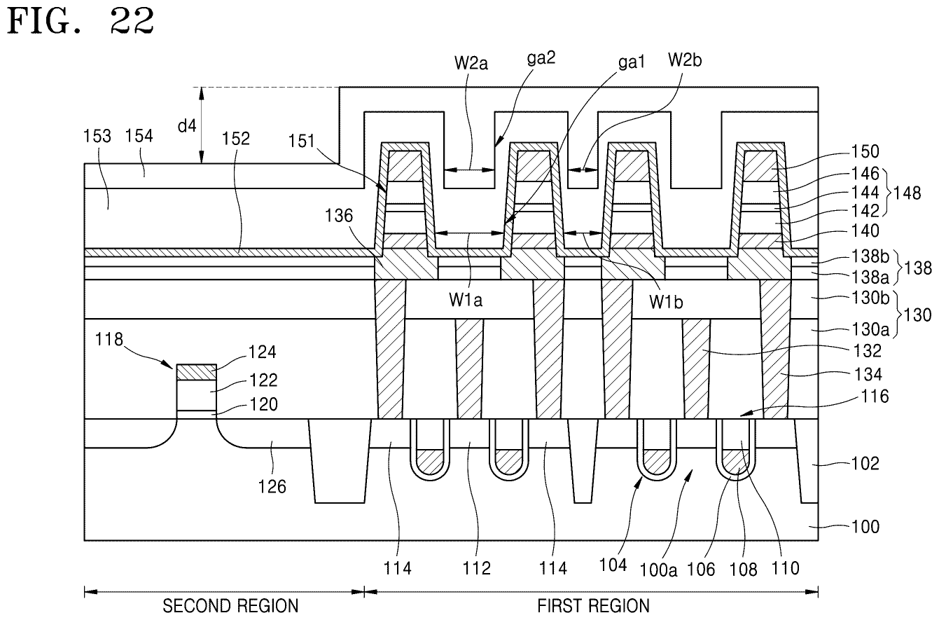

Referring to FIG. 22, a second buried layer 154 is formed using an insulating material on the first buried layer 153 to fill the second gap ga2 between the variable resistance pattern structures 151. The second buried layer 154 may be formed to have a sufficient thickness to fill the second gap ga2. The second buried layer 154 may include a material different from that of the first buried layer 153. In some embodiments, the second buried layer 154 may include a silicon oxide layer.

Due to the variable resistance pattern structure 151, the capping layer 152, and the second buried layer 154, the first region and the second region may have a step difference of d4. The step difference d4 may be a distance between an uppermost surface of the second buried layer 154 on the variable resistance pattern structure 151 and an uppermost surface of the second buried layer 154 on the pad isolation insulating layer 138.

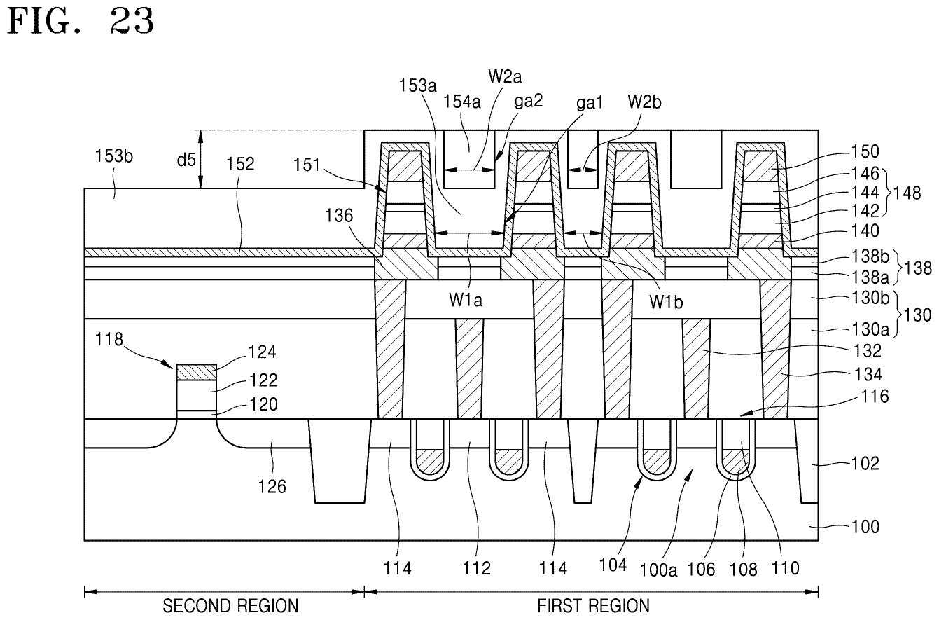

Referring to FIG. 23, the second buried layer 154 and the first buried layer 153 are sequentially etched back. Accordingly, the first buried layer pattern 153a and the second preliminary buried layer pattern 154a are formed between the variable resistance pattern structures 151 of the first region. In addition, the second interlayer insulating layer pattern 153b is formed in the second region.

When the first buried layer pattern 153a and the second preliminary buried layer pattern 154a are formed, the second buried layer 154 and the first buried layer 153 may be etched back by using the capping layer 152 in the first region as an etching stop point.

Due to the variable resistance pattern structure 151 and the second preliminary buried layer pattern 154a, the first region and the second region may have a step difference of d5. The step difference d5 may be a distance between an uppermost surface of the second preliminary buried layer pattern 154a on the variable resistance pattern structure 151 and an uppermost surface of the second interlayer insulating layer pattern 153b on the pad isolation insulating layer 138.

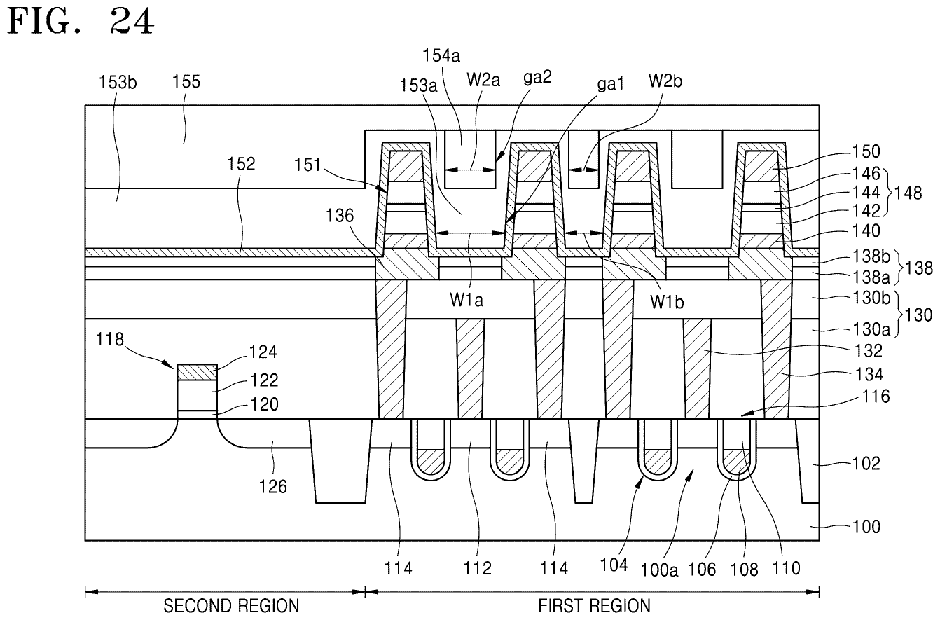

Referring to FIG. 24, a third interlayer insulating layer 155 is formed on the first buried layer pattern 153a, the second preliminary buried layer pattern 154a, and the second interlayer insulating layer pattern 153b. The third interlayer insulating layer 155 may include the same material as the first buried layer 153 or the first buried layer pattern 153a. The third interlayer insulating layer 155 may include a material having a low dielectric constant that is lower than that of silicon oxide.

The third interlayer insulating layer 155 may be formed to offset the step difference d5 between the first region and the second region shown in FIG. 15. In other words, the third interlayer insulating layer 155 may be buried in the lower region constituting the second region to offset the step difference d5 (FIG. 15) between the first region and the second region.

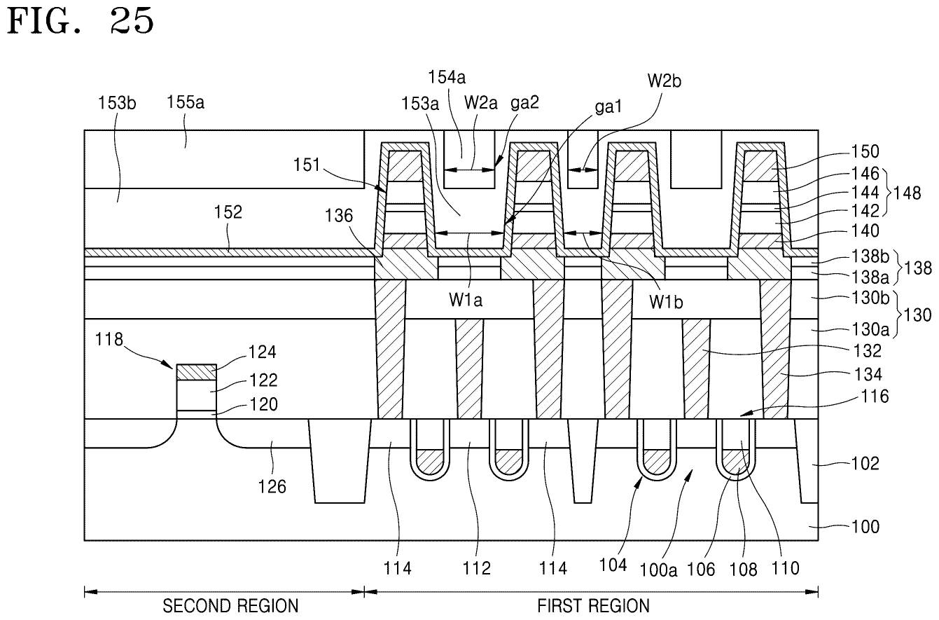

Referring to FIG. 25, the third interlayer insulating layer pattern 155a is formed in the second region by secondarily etching back the third interlayer insulating layer 155. The second etch-back may be performed using the second preliminary buried layer pattern 154a as an etch stop point. The step difference d5 (FIG. 15) between the first region and the second region may be offset due to the formation of the third interlayer insulating layer pattern 155a.

Subsequently, as shown in FIG. 8, after forming the fourth interlayer insulating layer pattern 156, the bit line 162 connected to the upper electrode of the variable resistance pattern structure 151 is formed in the fourth interlayer insulating layer pattern 156.

The fourth interlayer insulating layer pattern 156 may be formed by forming an insulating material layer on the variable resistance pattern structure 151, the capping layer 152, the first buried layer pattern 153a, the second preliminary buried layer pattern 154a, and the third interlayer insulating layer pattern 155a, and then patterning the insulating material layer.

When the fourth interlayer insulating layer pattern 156 is formed, the capping layer 152 may be patterned to form the capping layer pattern 152a, and the second preliminary buried layer pattern 154a may be the second buried layer pattern 154b. The bit line 162 may be formed by forming the barrier metal layer 162a and the metal layer 162b, and planarizing the barrier metal layer 162a and the metal layer 162b. The barrier metal layer 162a may include titanium, titanium nitride, tantalum, tantalum nitride, etc. The metal layer 162b may include copper, tungsten, aluminum, etc.

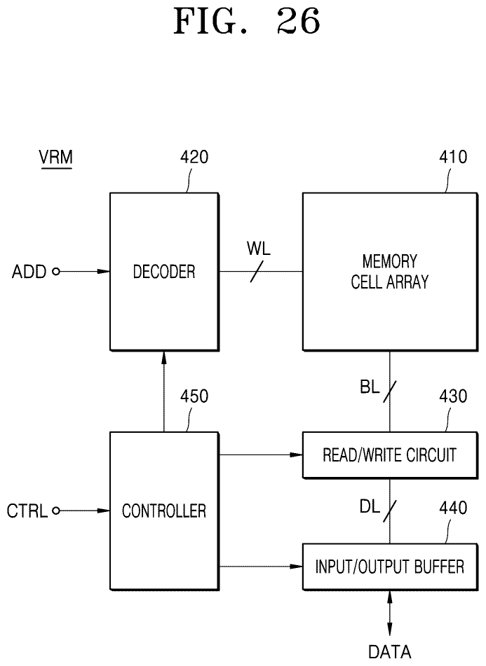

FIG. 26 is a block diagram of the variable resistance memory device VRM according to an embodiment.

Specifically, the variable resistance memory device VRM according to an embodiment includes a memory cell array 410, a decoder 420, a read/write circuit 430, an input/output buffer 440, and a controller 450. The memory cell array 410 has been described above and thus, a description thereof is omitted.

A plurality of memory cells in the memory cell array 410 are connected to the decoder 420 through word lines WL, and are connected to the read/write circuit 430 through bit lines BL.

The decoder 420 receives the external address ADD and decodes a row address and a column address to be accessed in the memory cell array 410 by the control of the controller 450 that operates according to a control signal CTRL.

The read/write circuit 430 receives data DATA from the input/output buffer 440 and a data line DL and writes the data DATA to a selected memory cell of the memory cell array 410 by the control of the controller 450, or provides the data DATA read from the selected memory cell of the memory cell array 410 to the input/output buffer 440 by the control of the controller 450.

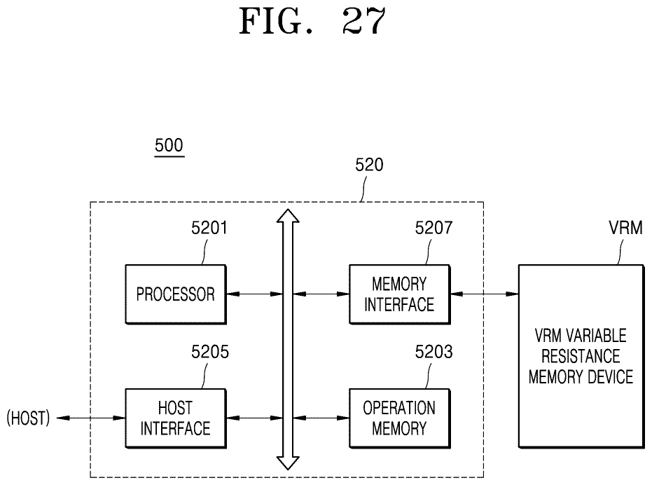

FIG. 27 is a block diagram of a data processing system 500 including the variable resistance memory device VRM according to an embodiment.

Specifically, the data processing system 500 may include a memory controller 520 connected between a host and the variable resistance memory device VRM. The memory controller 520 may be configured to access the variable resistance memory device VRM in response to a request from the host. The memory controller 520 may include a processor 5201, an operation memory 5203, a host interface 5205, and a memory interface 5207.

The processor 5201 may control the overall operation of the memory controller 520, and the operation memory 5203 may store applications, data, control signals, etc. required for the memory controller 520 to operate. The host interface 5205 performs protocol conversion for data/control signal exchange between the host and the memory controller 520.

The memory interface 5207 performs protocol conversion for data/control signal exchange between the memory controller 520 and the variable resistance memory device VRM. The variable resistance memory device VRM is the same as described above, and thus, a description thereof is omitted. The data processing system 500 according to an embodiment may be a memory card, but is not limited thereto.

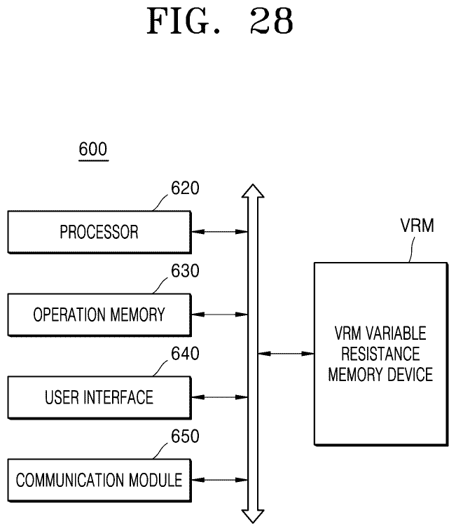

FIG. 28 is a block diagram of a data processing system 600 including the variable resistance memory device VRM according to an embodiment.

Specifically, the data processing system 600 includes the variable resistance memory device VRM, a processor 620, an operation memory 630, and a user interface 640, and may further include a communication module 650 if necessary. The processor 620 may be a central processing unit.

The operation memory 630 stores application programs, data, control signals, etc. necessary for the data processing system 600 to operate. The user interface 640 provides an environment in which a user may access the data processing system 600, and provides a data processing process, results, etc. of the data processing system 600 to the user.

The variable resistance memory device VRM is the same as described above, and thus, a description thereof is omitted. The data processing system 600 may be used as a disk device, as an internal/external memory card of a portable electronic device, or as an image processor and other application chipsets.

While the inventive concept has been particularly shown and described with reference to embodiments thereof, it will be understood that various changes in form and details may be made therein without departing from the spirit and scope of the following claims.

What is claimed is:

1. A variable resistance memory device comprising:
a substrate comprising a first region and a second region;
a plurality of memory cells disposed in the first region and each memory cell of the plurality of memory cells spaced apart from each other;
a buried layer pattern buried between adjacent memory cells of the plurality of memory cells in the first region, the buried layer pattern comprising a first buried layer pattern filling a lower portion of each of the plurality of memory cells and a second buried layer pattern filling an upper portion of each of the plurality of memory cells on the first buried layer pattern, and the first buried pattern layer comprising a first material and the second buried layer pattern comprising a second material different from the first material; and
an interlayer insulating layer pattern disposed in the second region and comprising the first material.

2. The variable resistance memory device of claim 1, wherein the first region is a cell array region, and the second region is a peripheral circuit region.

3. The variable resistance memory device of claim 1, wherein
the second buried layer pattern includes a silicon oxide layer; and
the first buried layer pattern and the interlayer insulating layer pattern each include a material having a lower dielectric constant than that of the silicon oxide layer.

4. The variable resistance memory device of claim 1, wherein
the memory cells of the plurality of memory cells each include a variable resistance pattern structure, and
the variable resistance pattern structure has a structure in which a lower electrode, a magnetic tunnel junction pattern, and an upper electrode are stacked.

5. The variable resistance memory device of claim 1, wherein the second buried layer pattern is located within the first buried layer pattern and is buried in part of an upper portion of the first buried layer pattern.

6. The variable resistance memory device of claim 1, wherein portions of the second buried layer pattern that are buried between adjacent memory cell of the plurality of memory cells have different widths from each other.

7. The variable resistance memory device of claim 1, wherein the second buried layer pattern is disposed to be biased to one side relative to a center of the first buried layer pattern.

8. The variable resistance memory device of claim 1, wherein
the memory cells of the plurality of memory cells each include a variable resistance pattern structure,
each variable resistance pattern structure has a structure in which a lower electrode, a magnetic tunnel junction pattern, and an upper electrode are stacked,
a capping layer pattern is formed on opposing sidewalls of each variable resistance pattern structure, and
a width of the second buried layer pattern is greater than a distance from one sidewall of the second buried layer pattern to one sidewall of the capping layer pattern.

9. The variable resistance memory device of claim 1, wherein
the memory cells of the plurality of memory cells each include a variable resistance pattern structure,
each variable resistance pattern structure has a structure in which a lower electrode, a magnetic tunnel junction pattern, and an upper electrode are stacked, and
a bottom surface of the second buried layer pattern is located at the same height a bottom surface of the upper electrode in a vertical direction.

10. A variable resistance memory device comprising:
a substrate comprising a first region and a second region;
a plurality of memory cells disposed in the first region and each memory cell of the plurality of memory cells spaced apart from each other, and each memory cell comprising a variable resistance pattern structure comprising a lower electrode, a magnetic tunnel junction pattern, and an upper electrode;
a buried layer pattern buried between adjacent memory cells of the plurality of memory cells in the first region, the buried layer pattern comprising a first buried layer pattern filling a first gap between lower portions of adjacent memory cells of the plurality of memory cells, and a second buried layer pattern filling a second gap between upper portions of adjacent memory cells of the plurality of memory cells on the first buried layer pattern, a width of the second gap being less than a width of the first gap, and the first buried layer pattern comprising a first material and the second buried layer pattern comprising a second material different than the first material; and
an interlayer insulating layer pattern disposed in the second region and comprising the first material.

11. The variable resistance memory device of claim 10, wherein
a capping layer pattern is formed on opposing sidewalls of each variable resistance pattern structure, and
a width of the second buried layer pattern is equal to a distance from one sidewall of the second buried layer pattern to one sidewall of the capping layer pattern.

12. The variable resistance memory device of claim 10, wherein
the second buried layer pattern includes a silicon oxide layer; and
the first buried layer pattern and the interlayer insulating layer pattern each include a material having a lower dielectric constant than that of the silicon oxide layer.

13. The variable resistance memory device of claim 10, wherein
the second buried layer pattern is located within the first buried layer pattern in part of an upper portion of the first buried layer pattern and disposed to be biased to one side relative to a center of the first buried layer pattern.

14. The variable resistance memory device of claim 10, wherein
the interlayer insulating layer pattern includes a lower interlayer insulating layer pattern formed to a thickness corresponding to that of the first buried layer pattern and an upper interlayer insulating layer pattern formed to a thickness corresponding to that of the second buried layer pattern, and
the first buried layer pattern has the same shape as the lower interlayer insulating layer pattern.

15. A variable resistance memory device comprising:
a substrate comprising a first region and a second region;
a plurality of pad electrodes with the pad electrodes disposed apart from each other on the substrate in the first region;
a pad isolation insulating layer disposed between adjacent pad electrodes of the plurality of pad electrodes in the first region and on the substrate in the second region;
variable resistance pattern structures spaced apart from each other, each disposed on a respective pad electrode of the plurality of pad electrodes in the first region, and each having a structure in which a lower electrode, a magnetic tunnel junction pattern, and an upper electrode are stacked;
a buried layer pattern buried between adjacent variable resistance pattern structures in the first region, the buried layer pattern comprising a first buried layer pattern filling a first gap between lower portions of the adjacent variable resistance pattern structures, and a second buried layer pattern filling a second gap between upper portions of the adjacent variable resistance pattern structures on the first buried layer pattern, a width of the second gap being less than a width of the first gap, and the first buried layer pattern comprising first material and the second buried layer pattern comprising a second material different than the first material; and
an interlayer insulating layer pattern disposed in the second region and comprising the first material.

16. The variable resistance memory device of claim 15, wherein
the pad isolation insulating layer includes a first pad isolation insulating layer and a second pad isolation insulating layer,
the second pad isolation insulating layer includes a silicon oxide layer, and
the first pad isolation insulating layer includes a material having a lower dielectric constant than that of the silicon oxide layer.

17. The variable resistance memory device of claim 15, wherein
the second buried layer pattern includes a silicon oxide layer, and
the first buried layer pattern and the interlayer insulating layer pattern each include a material having a lower dielectric constant than that of the silicon oxide layer.

18. The variable resistance memory device of claim 15, wherein a width of each of the variable resistance pattern structures is less than a width of each of the plurality of pad electrodes.

19. The variable resistance memory device of claim 15, wherein
the second buried layer pattern is disposed to be biased to one side relative to a center of the first buried layer pattern,
a capping layer pattern is formed on opposing sidewalls of each of the variable resistance pattern structures, and
a width of the second buried layer pattern is greater than, less than, or equal to a distance from one sidewall of the second buried layer pattern to one sidewall of the capping layer pattern.

20. The variable resistance memory device of claim 15, wherein a bottom surface of the second buried layer pattern is located to the same level as a bottom surface of the upper electrode in a vertical direction.
